(19) United States
(12) Patent Application Publication
(10) Pub. No.: US 2024/0147772 A1
(43) Pub. Date: May 2, 2024

(54) DISPLAY PANEL AND MANUFACTURING METHOD THEREOF

(71) Applicant: Samsung Display Co., Ltd., Yongin-si (KR)

(72) Inventors: SUBIN BAE, Yongin-si (KR); DAWOON JUNG, Yongin-si (KR); YU-GWANG JEONG, Yongin-si (KR); TAEWOOK KANG, Yongin-si (KR); SANGGAB KIM, Yongin-si (KR); SUNGWON CHO, Yongin-si (KR)

(21) Appl. No.: 18/463,648

(22) Filed: Sep. 8, 2023

(30) Foreign Application Priority Data
Oct. 28, 2022 (KR) 10-2022-0140823

(51) Int. Cl. H10K 59/122; H10K 59/12; H10K 59/35; H10K 59/80; H10K 59/88

(52) U.S. Cl. CPC H10K 59/122; H10K 59/1201; H10K 59/35; H10K 59/873; H10K 59/88; H10K 2102/351

(57) ABSTRACT

A display panel includes a base layer, a circuit layer, a light emitting element layer, and an encapsulation layer. The light emitting element layer includes a lower electrode on the circuit layer, a lower pixel defining film that covers a portion of the lower electrode to define a light emitting opening portion and is on the circuit layer, a light emitting pattern inside the light emitting opening portion and on the lower electrode, an upper electrode on the light emitting pattern, and an upper pixel defining film that defines an upper opening portion and is on the lower pixel defining film. The encapsulation layer includes a first inorganic encapsulation film on the upper electrode and the upper pixel defining film, and a transparent conductive oxide film on the first inorganic encapsulation film.

### CROSS-REFERENCE TO RELATED APPLICATIONS

The present application claims priority to and the benefit of Korean Patent Application No. 10-2022-0140823, filed on Oct. 28, 2022, the entire contents of which are hereby incorporated by reference.

### BACKGROUND

### 1. Field

Aspects of some embodiments of the present disclosure herein relate to a display panel and a manufacturing method thereof.

### 2. Description of the Related Art

Display panels are used in various types of multimedia devices, such as televisions, mobile phones, tablet computers and game consoles, in order to display image information to users. The display panels each include a light emitting element and a pixel circuit for driving the light emitting element. The light emitting element included in the display panel emits light and generates or displays images according to a voltage applied from the pixel circuit. In order to achieve relatively high resolution and improve reliability, the development of a patterning method for the light emitting element may be desirable.

The above information disclosed in this Background section is only for enhancement of understanding of the background and therefore the information discussed in this Background section does not necessarily constitute prior art.

### SUMMARY

Aspects of some embodiments of the present disclosure herein relate to a display panel and a manufacturing method thereof, and for example, to a display panel capable of achieving high resolution and having improved processability, and a method for manufacturing the display panel.

Aspects of some embodiments of the present disclosure include a display panel capable of achieving relatively high resolution.

Aspects of some embodiments of the present disclosure may also include a display panel manufacturing method that may be capable of providing relatively improved processability.

According to some embodiments of the present disclosure a display panel includes a base layer, a circuit layer on the base layer, a light emitting element layer on the circuit layer, and an encapsulation layer on the light emitting element layer. The light emitting element layer includes a lower electrode on the circuit layer, a lower pixel defining film, which covers a portion of the lower electrode to define a light emitting opening portion and is on the circuit layer, a light emitting pattern inside the light emitting opening portion and on the lower electrode, an upper electrode on the light emitting pattern, and an upper pixel defining film which defines an upper opening portion and is on the lower pixel defining film. The encapsulation layer includes a first inorganic encapsulation film on the upper electrode and the upper pixel defining film, and a transparent conductive oxide film on the first inorganic encapsulation film.

According to some embodiments, the transparent conductive oxide film may have a thickness of about 500 Å to about 2000 Å.

According to some embodiments, the transparent conductive oxide film may include a first transparent conductive oxide film inside the upper opening portion, and a second transparent conductive oxide film on the upper pixel defining film.

According to some embodiments, a thickness of the first transparent conductive oxide film and a thickness of the second transparent conductive oxide film may be equal to each other.

According to some embodiments, the display panel may further include a transparent conductive oxide film opening portion defined by the second transparent conductive oxide film on the upper pixel defining film.

According to some embodiments, the light emitting element layer may further include a protective pattern on the lower electrode and covered by the lower pixel defining film.

According to some embodiments, the upper pixel defining film may include a first inorganic film on the lower pixel defining film, and a second inorganic film on the first inorganic film.

According to some embodiments, the second inorganic film may have a side surface that more protrudes toward a center of the lower electrode than a side surface of the first inorganic film in a plan view.

According to some embodiments, each of the first inorganic film and the second inorganic film may include an inorganic insulation film or a conductive metal.

According to some embodiments, the upper pixel defining film may further include a third inorganic film above the lower pixel defining film and below the first inorganic film, and the third inorganic film may have a side surface that more protrudes toward a center of the upper opening portion than a side surface of the first inorganic film in a plan view.

According to some embodiments, the light emitting element layer may further include a capping pattern on the upper electrode. The encapsulation layer may further include an organic encapsulation film, which is on the first inorganic encapsulation film and the transparent conductive oxide film, and a second inorganic encapsulation film which is on the organic encapsulation film.

According to some embodiments of the present disclosure, a display panel includes a base layer, a circuit layer on the base layer, and a light emitting element layer on the circuit layer. The light emitting element layer includes a lower electrode on the circuit layer, a lower pixel defining film that is on the circuit layer and covers a portion of the lower electrode to define a light emitting opening portion, a first light emitting pattern inside the light emitting opening portion and on the lower electrode, an upper electrode on the first light emitting pattern, an upper pixel defining film on the lower pixel defining film, and a dummy pattern on the upper pixel defining film. The dummy pattern comprises a first dummy pattern and a second dummy pattern that are on the same layer.

According to some embodiments, the light emitting element layer further comprises a second light emitting pattern which emits light of a color different from that of the first light emitting pattern, the first dummy pattern may include a light emitting material the same as a light emitting material included in the first light emitting pattern, and the second dummy pattern may include a light emitting material the same as a light emitting material included in the second light emitting pattern.

According to some embodiments, the display panel may further include an encapsulation layer on the light emitting element layer. The encapsulation layer may include a first inorganic encapsulation film, which is on the upper electrode and the upper pixel defining film, and a transparent conductive oxide film which is on the first inorganic encapsulation film.

According to some embodiments, the light emitting element layer may further include a protective pattern on the lower electrode and covered by the lower pixel defining film.

According to some embodiments of the present disclosure, a display panel manufacturing method includes preparing a preliminary display panel, which includes a base layer, a circuit layer on the base layer, first to third lower electrodes on the circuit layer and spaced apart from each other, a preliminary lower pixel defining film that is on the circuit layer and covers the first to third lower electrodes, and a preliminary upper pixel defining film on the preliminary lower pixel defining film, removing regions of the preliminary upper pixel defining film, each of which has at least a portion overlapping each of the first to third lower electrodes in a plan view, to form an upper pixel defining film that defines each of first to third upper opening portions, removing portions of the preliminary lower pixel defining film, which are exposed by the first to third upper opening portions, to form a lower pixel defining film that defines first to third light emitting opening portions, depositing a first light emitting material on the first to third lower electrodes and the upper pixel defining film to form a first light emitting pattern and a first-1 dummy pattern, forming a first upper electrode and a first-2 dummy pattern on the first light emitting pattern and the first-1 dummy pattern, respectively, so as to be in contact with at least a portion of a side surface of the upper pixel defining film on the first light emitting pattern, forming a first inorganic encapsulation film so as to cover the first upper electrode, the first-1 dummy pattern, the first-2 dummy pattern, and the upper pixel defining film, forming a transparent conductive oxide film on the first inorganic encapsulation film, and first removing the transparent conductive oxide film, the first inorganic encapsulation film, the first-1 dummy pattern, and the first-2 dummy pattern of a first removal region other than a first region that overlaps the first light emitting pattern and a portion of the upper pixel defining film surrounding the first light emitting pattern in a plan view.

According to some embodiments, the first removing may include forming a first mask pattern on the first region, removing the transparent conductive oxide film of the first removal region by wet etching, and removing the first inorganic encapsulation film, the first-1 dummy pattern, and the first-2 dummy pattern of the first removal region by dry etching.

According to some embodiments, the display panel manufacturing method may further include depositing a second light emitting material on the first region and the first removal region to form a second light emitting pattern and a second-1 dummy pattern, forming a second upper electrode and a second-2 dummy pattern on the second light emitting pattern and the second-1 dummy pattern, respectively, so as to be in contact with at least a portion of the side surface of the upper pixel defining film, forming the first inorganic encapsulation film so as to cover the second upper electrode, the second-1 dummy pattern, the second-2 dummy pattern, and the upper pixel defining film, forming the transparent conductive oxide film on the first inorganic encapsulation film, and second removing the transparent conductive oxide film, the first inorganic encapsulation film, the second-1 dummy pattern, and the second-2 dummy pattern of a second removal region other than a second region that overlaps the second light emitting pattern and a portion of the upper pixel defining film surrounding the second light emitting pattern in a plan view. The second removing may include forming a second mask pattern on the second region.

According to some embodiments, the display panel manufacturing method may further include depositing a third light emitting material on the second region and the second removal region to form a third light emitting pattern and a third-1 dummy pattern, forming a third upper electrode and a third-2 dummy pattern on the third light emitting pattern and the third-1 dummy pattern, respectively, so as to be in contact with at least a portion of the side surface of the upper pixel defining film, forming the first inorganic encapsulation film so as to cover the third upper electrode, the third-1 dummy pattern, the third-2 dummy pattern, and the upper pixel defining film, forming the transparent conductive oxide film on the first inorganic encapsulation film, and third removing the transparent conductive oxide film, the first inorganic encapsulation film, the third-1 dummy pattern, and the third-2 dummy pattern of a third removal region other than a third region that overlaps the third light emitting pattern and a portion of the upper pixel defining film surrounding the third light emitting pattern in a plan view. The third removing may include forming a third mask pattern on the third region.

According to some embodiments, the display panel manufacturing method may further include removing the first to third mask patterns by stripping.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is an assembled perspective view of a display device according to some embodiments of the present disclosure;

FIG. 2 is an exploded perspective view of a display device according to some embodiments of the present disclosure;

FIG. 3 is a cross-sectional view of a display module according to some embodiments of the present disclosure;

FIG. 4 is a plan view of a display panel according to some embodiments of the present disclosure;

FIG. 5 is an exploded plan view of a portion of an active region according to some embodiments of the present disclosure;

FIGS. 6A to 6C are cross-sectional views of a display panel according to some embodiments of the present disclosure taken along line I-I′ in FIG. 5;

FIG. 7 is a flowchart of a display panel manufacturing method according to some embodiments of the present disclosure;

FIGS. 8A to 8C are cross-sectional views illustrating some operations, respectively, of a display panel manufacturing method according to some embodiments of the present disclosure;

FIGS. 9A to 9C are cross-sectional views illustrating some operations, respectively, of a display panel manufacturing method according to some embodiments of the present disclosure;

FIGS. 10A and 10B are cross-sectional views illustrating some operations, respectively, of a display panel manufacturing method according to some embodiments of the present disclosure;

FIGS. 11A to 11G are cross-sectional views illustrating some operations, respectively, of a display panel manufacturing method according to some embodiments of the present disclosure;

FIGS. 12A to 12C are cross-sectional views illustrating some operations, respectively, of a display panel manufacturing method according to some embodiments of the present disclosure;

FIGS. 13A to 13C are cross-sectional views illustrating some operations, respectively, of a display panel manufacturing method according to some embodiments of the present disclosure;

FIG. 14 is a cross-sectional view illustrating some operations of a display panel manufacturing method according to some embodiments of the present disclosure; and

FIGS. 15A and 15B are cross-sectional views illustrating some operations, respectively, of a display panel manufacturing method according to some embodiments of the present disclosure.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will more fully convey the scope of embodiments according to the present invention to those skilled in the art.

It will be understood that when an element (or region, layer, section, etc.) is referred to as being “on”, “connected to” or “coupled to” another element, it can be located directly on, connected or coupled to the other element or a third intervening elements may be located between the elements.

In the present disclosure, being “directly located” may mean that there is no additional layer, film, region, substrate or the like between a part such as a layer, film, region or substrate, and another part. For example, being “directly located” may refer to two layers or two members are arranged with no additional member such as an adhesive member, used therebetween.

Like reference numbers or symbols refer to like elements throughout. In addition, in the drawings, the thickness, the ratio, and the dimension of elements are exaggerated for effective description of the technical contents.

The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing. In the present disclosure, being “located on” may be referred to as being located not only above any one member but also below the member.

It will be further understood that the terms such as “includes” and “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to the accompanying drawings.

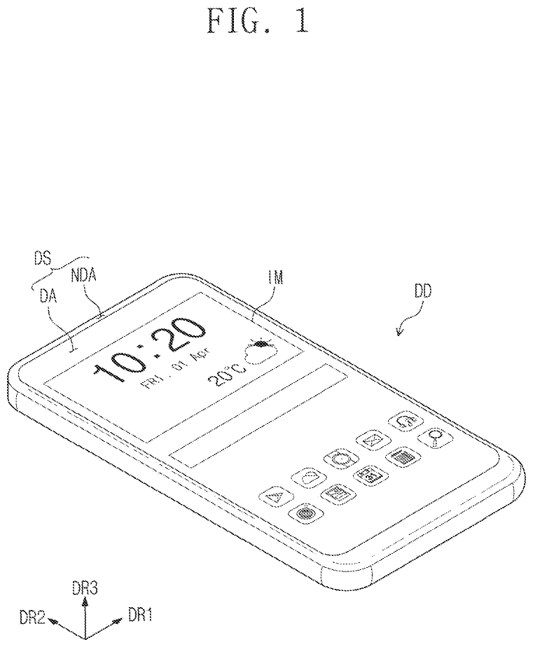

FIG. 1 is an assembled perspective view of a display device DD according to some embodiments of the present invention.

The display device DD according to some embodiments may be a device activated in response to an electrical signal. For example, the display device DD may be a large-sized electronic device such as a television, a monitor, or an outdoor billboard. In addition, the display device DD may be a small and medium-sized electronic device such as a personal computer, a notebook computer, a personal digital assistant, a vehicle navigation unit, a game console, a mobile phone, a tablet computer, or a camera. However, these are examples, and embodiments according to the present disclosure are not limited thereto. FIG. 1 illustrates a mobile phone as an example of the display device DD.

In FIG. 1 and the following drawings, a first direction DR1, a second direction DR2, and a third direction DR3 are illustrated, and directions indicated by the first to third directions DR1, DR2 and DR3 used herein are relative concepts and may be changed to other directions. In addition, first to third directions may be directions opposite to the directions respectively indicated by the first to third directions DR1, DR2 and DR3 and may be designated by the same/similar reference numbers or symbols.

Referring to FIG. 1, the display device DD according to some embodiments may include a display surface DS defined by the first direction DR1 and the second direction DR2 crossing the first direction DR1. The display device DD may display images IM to users through the display surface DS. The display device DD according to some embodiments may display the images IM in the third direction DR3 on the display surface DS parallel to each of the first direction DR1 and the second direction DR2. In the present disclosure, a front surface (or top surface) and a rear surface (or bottom surface) of each member is defined on the basis of a direction in which the image IM is displayed. The front surface and the rear surface may oppose each other in the third direction DR3, and a normal direction to each of the front surface and the rear surface may be parallel to the third direction DR3.

According to some embodiments, the display surface DS may include a display region DA and a non-display region NDA adjacent to the display region DA. The non-display region NDA may be a region on which the image IM is not displayed. However, embodiments according to the present disclosure are not limited thereto, and according to some embodiments the non-display region NDA may be omitted.

The display device DD according to some embodiments may detect an external input applied from the outside. The external input may include various types of inputs provided from the outside of the display device DD. For example, the external input may include not only a touch by a body part, such as a user's hand, but also an external input (e.g., hovering) applied by approaching or being adjacent to the display device DD by a distance (e.g., a set or predetermined distance). In addition, the external input may have various types such as force, pressure, temperature, and light.

The display device DD according to some embodiments may further include various electronic modules. For example, the electronic modules may include at least one of a camera, a speaker, a light detecting sensor, or a heat detecting sensor. The electronic module may detect an external subject received through the display surface DS or provide the outside with a sound signal such as voice, through the display surface DS. The electronic module may include a plurality of components, and is not limited to any one embodiment.

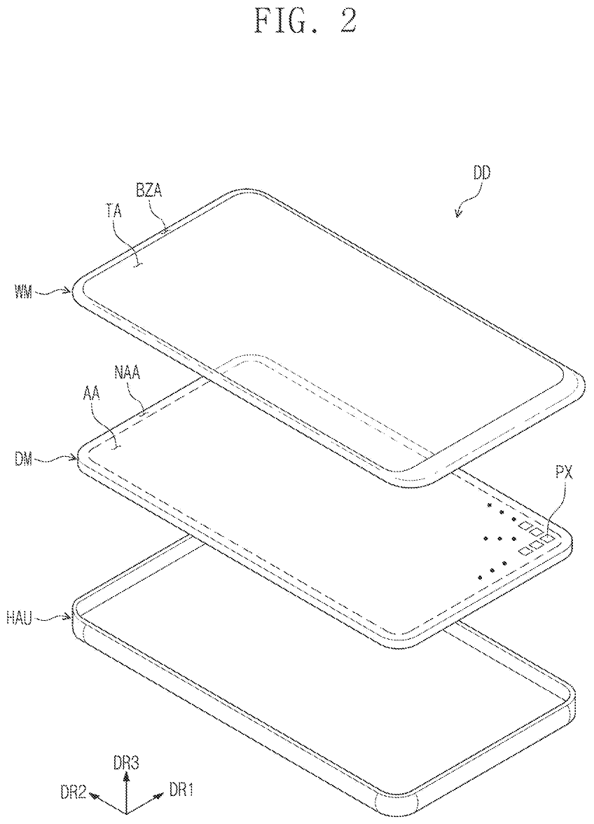

FIG. 2 is an exploded perspective view of a display device DD according to some embodiments of the present disclosure. FIG. 2 is an exploded perspective view of the display device DD in FIG. 1 according to some embodiments of the present disclosure.

Referring to FIG. 2, the display device DD according to some embodiments may include a display module DM and a window WM located on the display module DM. The window WM may be located above or below or on both sides of the display module DM. FIG. 2 illustrates that the window WM is located above the display module DM.

The display device DD according to some embodiments may further include an electronic module located below the display module DM. For example, the electronic module may include a camera module.

According to some embodiments, the display device DD according to some embodiments may further include an adhesive layer and/or a polarizing film located between the display module DM and the window WM. According to some embodiments, the display device DD according to some embodiments may further include a lower functional layer located below the display module DM.

The display device DD according to some embodiments may further include a housing HAU that accommodates the display module DM, the lower functional layer, and so on. The housing HAU may be coupled to the window WM and constitute an outer appearance of the display device DD. The housing HAU may include a material having relatively high strength. For example, the housing HAU may include a plurality of frames and/or plates made of glass, plastic, or metal. The display module DM may be accommodated in an accommodation space and protected from external impact.

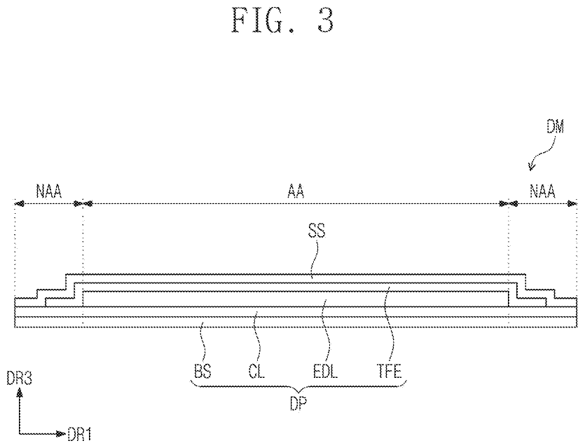

The display module DM according to some embodiments may display the images IM (see FIG. 1) in response to an electrical signal and transmit/receive information of an external input. The display module DM may include a display panel DP (see FIG. 3) and a sensor layer SS (see FIG. 3) located on the display panel DP (see FIG. 3).

The display module DM may include an active region AA and a peripheral region NAA. The active region AA may be a region through which the image IM (see FIG. 1) is provided. A pixel PX may be located in the active region AA. The peripheral region NAA may be adjacent to the active region AA. The peripheral region NAA may surround the active region AA. A driving circuit or driving wiring for driving the active region AA may be located in the peripheral region NAA.

The display module DM may include a plurality of pixels PX. Each of the pixels PX may emit light in response to an electrical signal. The light emitted by each of the pixels PX may form the image IM (see FIG. 1). Each of the pixels PX may include a display element. For example, the display element may be an organic light emitting element, an inorganic light emitting element, an organic-inorganic light emitting element, a micro LED, a nano LED, a quantum dot light emitting element, an electrophoresis element, an electrowetting element, or the like.

The window WM may cover the entirety of a top surface of the display module DM. The window WM may have a shape corresponding to the shape of the display module DM. The window WM may have flexibility that allows a change in shape according to folding or bending of the display device DD. The window WM may function to protect the display module DM from an external impact.

The window WM includes a transmission region TA and a bezel region BZA. The transmission region TA may overlap at least a portion of the active region AA of the display module DM. The transmission region TA may be an optically transparent region. For example, the transmission region TA may have a transmittance of about 90% or higher at a wavelength of visible light ranges. The image IM (see FIG. 1) may be provided for a user through the transmission region TA, and the user may receive information through the image IM (see FIG. 1).

The bezel region BZA may have a relatively lower light transmittance than the transmission region TA. The bezel region BZA may define a shape of the transmission region TA. The bezel region BZA may have a color (e.g., a set or predetermined color). The bezel region BZA may cover the peripheral region NAA of the display module DM and block the peripheral region NAA from being visible from the outside. However, this is an example, and the bezel region BZA may be omitted in the window WM according to some embodiments.

FIG. 3 is a cross-sectional view of a display module DM according to some embodiments of the present disclosure.

Referring to FIG. 3, the display module DM may include a display panel DP and a sensor layer SS located on the display panel DP. An active region AA and a peripheral region NAA, which are illustrated in FIG. 3, may correspond to the active region AA and the peripheral region NAA, respectively, which are illustrated in FIG. 2.

The display panel DP may include a base layer BS, a circuit layer CL, a light emitting element layer EDL, and an encapsulation layer TFE.

The base layer BS may be a member that provides a base surface on which the circuit layer CL is located. The base layer BS may be a rigid substrate or a flexible substrate that is bendable, foldable, rollable, or the like. The base layer BS may be a glass substrate, a metal substrate, a polymer substrate, etc. However, embodiments according to the present disclosure are not limited thereto, and the base layer BS may be an inorganic layer, an organic layer, or a composite material layer.

The circuit layer CL may be located on the base layer BS. The circuit layer CL may include an insulation layer, a semiconductor pattern, a conductive pattern, a signal line, etc. The insulation layer, a semiconductor layer, and a conductive layer may be formed on the base layer BS through coating, deposition or the like, and then, the insulation layer, the semiconductor layer and the conductive layer may be selectively patterned by performing a photolithography process and an etching process multiple times. Thereafter, the semiconductor pattern, the conductive pattern, and the signal line, which are included in the circuit layer CL, may be formed.

The light emitting element layer EDL may be located on the circuit layer CL. The light emitting element layer EDL may include a light emitting element. For example, the light emitting element may include an organic light emitting material, an inorganic light emitting material, an organic-inorganic light emitting material, a quantum dot, a quantum rod, a micro LED or a nano LED.

The encapsulation layer TFE may be located on the light emitting element layer EDL. The encapsulation layer TFE may cover the light emitting element EDL. The encapsulation layer TFE may protect the light emitting element layer EDL from moisture, oxygen, and foreign matters such as dust particles.

The sensor layer SS may be located on the display panel DP. The sensor layer SS may detect an external input applied from the outside. The external input may be a user's input. The user's input may include various types of external inputs such as a part of a user's body, light, heat, pen, or pressure. For example, the sensor layer SS may detect an external input by using a capacitance method. According to some embodiments of the present disclosure, an operation manner of the sensor layer SS is not particularly limited, and the sensor layer SS may detect the external input by using an electromagnetic induction method or a pressure detection method.

The sensor layer SS may be formed on the display panel DP through a continuous process. In this case, the sensor layer SS may be located directly on the display panel DP. Here, being “located directly” may mean that a third component is not located between the sensor layer SS and the display layer DP. That is, a separate adhesive member may not be located between the sensor layer SS and the display layer DP. For example, the sensor layer SS may be located directly on the encapsulation layer TFE of the display layer DP. Alternatively, the sensor layer SS may be bonded to the display layer DP through an adhesive member. The adhesive member may include a common adhesive or an adhesive agent.

The sensor layer SS may have a multilayer structure. The sensor layer SS may include a conductive layer having a single-layer or multilayer structure. The sensor layer SS may include an insulation layer having a single-layer or multilayer structure.

An optical layer may be further located on the sensor layer SS. The optical layer may be located directly on the sensor layer SS. The optical layer may be formed on the sensor layer SS through a continuous process. The optical layer may reduce the reflectance of external light incident from the outside of the display module DM. The optical layer may include a polarizing layer or a color filter layer.

According to some embodiments, the sensor layer SS may be omitted and the optical layer may be located directly on the display panel DP. According to some embodiments, the positions of the sensor layer SS and the optical layer may be switched.

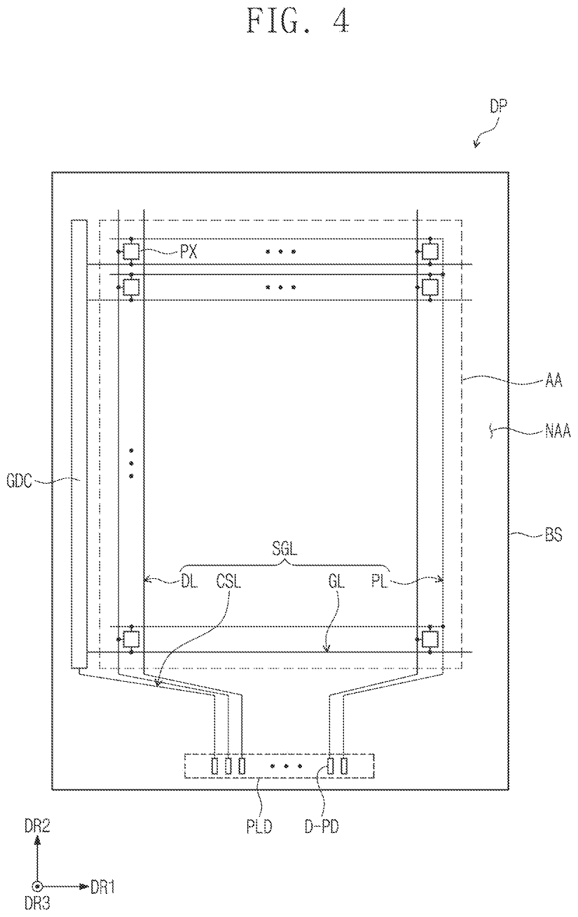

FIG. 4 is a plan view of a display panel DP according to some embodiments of the present disclosure.

Referring to FIG. 4, the display panel DP may include a base layer BS divided into an active region AA and a peripheral region NAA.

The display panel DP may include pixels PX located in the active region AA, and signal lines SGL electrically connected to the pixels PX. The display panel DP may include a driving circuit GDC and a pad part PLD that are located in the peripheral region NAA.

The pixels PX may be arranged in the first direction DR1 and the second direction DR2. The pixels PX may include a plurality of pixel rows, which extend in the first direction DR1 and are arranged in the second direction DR2, and a plurality of pixel columns which extend in the second direction DR2 and are arranged in the first direction DR1.

The signal lines SGL may include gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be electrically connected to the pixels PX. The control signal line CSL may be connected to the driving circuit GDC and provide the driving circuit GDC with control signals.

The driving circuit GDC may include a gate driving circuit. The gate driving circuit may generate gate signals and sequentially output the generated gate signals to the gate lines GL. The gate driving circuit may further output another control signal to a pixel driving circuit.

The pad part PLD may be a part to which a flexible circuit board is connected. The pad part PLD may include pixel pads D-PD, and the pixel pads D-PDn may be pads for connecting the flexible circuit board to the display panel DP. Each of the pixel pads D-PD may be connected to a corresponding signal line among the signal lines SGL. The pixel pads D-PD may be connected to corresponding pixels PX through the signal lines SGL, respectively. One pixel pad among the pixel pads D-PD may be connected to the driving circuit GDC.

The pad part PLD may further include input pads. The input pads may be pads for connecting the flexible circuit board to the sensor layer SS (see FIG. 3). However, embodiments of the present disclosure are not limited thereto, and the input pads may be located on the sensor layer SS (see FIG. 3) and connected to a circuit board separate from the flexible circuit board on which the pixel pads D-PD are located. Alternatively, the sensor layer SS (see FIG. 3) may be omitted, and the input pads may not be further included.

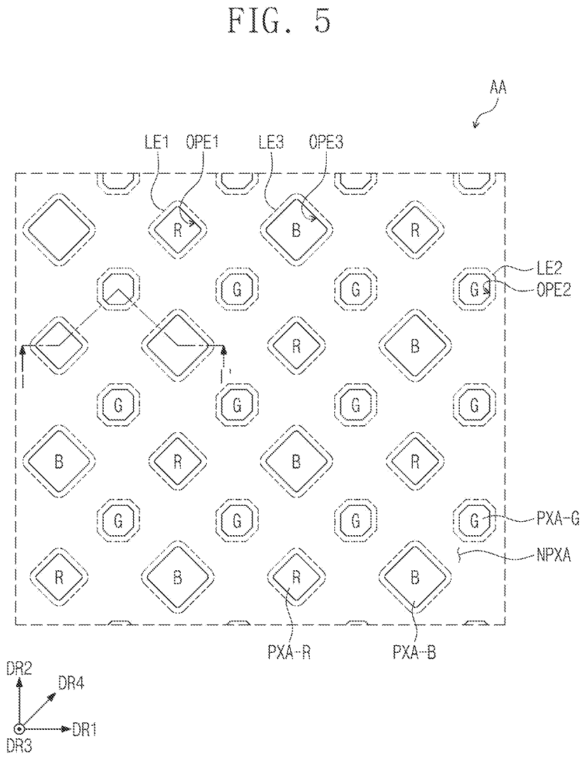

FIG. 5 is an exploded plan view of a portion of an active region AA according to some embodiments of the present disclosure. FIG. 5 is an expanded plan view of the active region AA of the display module DM (see FIG. 2) when viewed from above the display surface DS (e.g., in a plan view) (see FIG. 1).

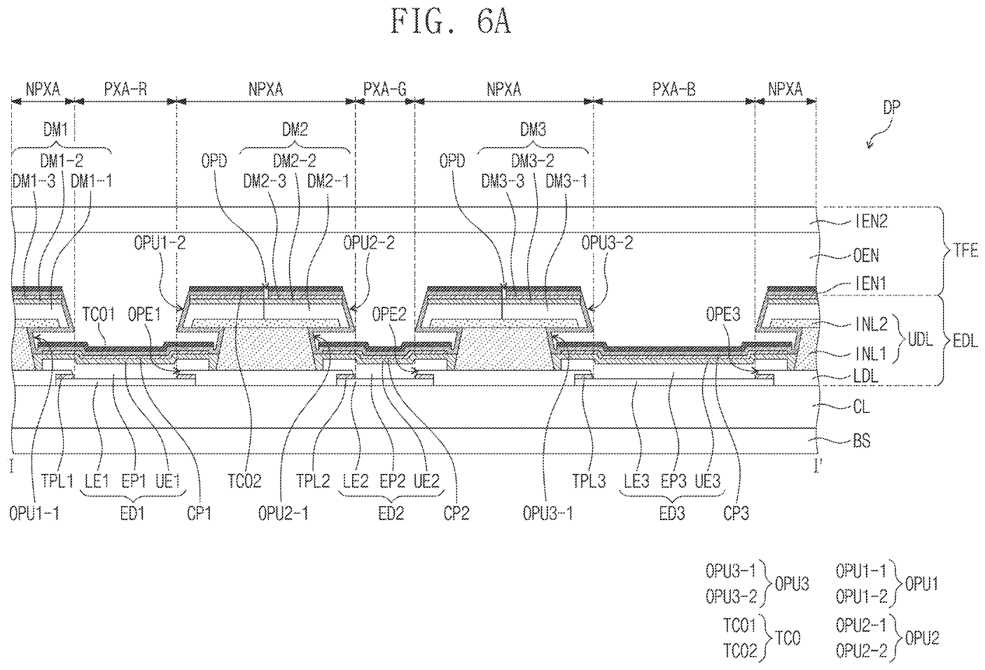

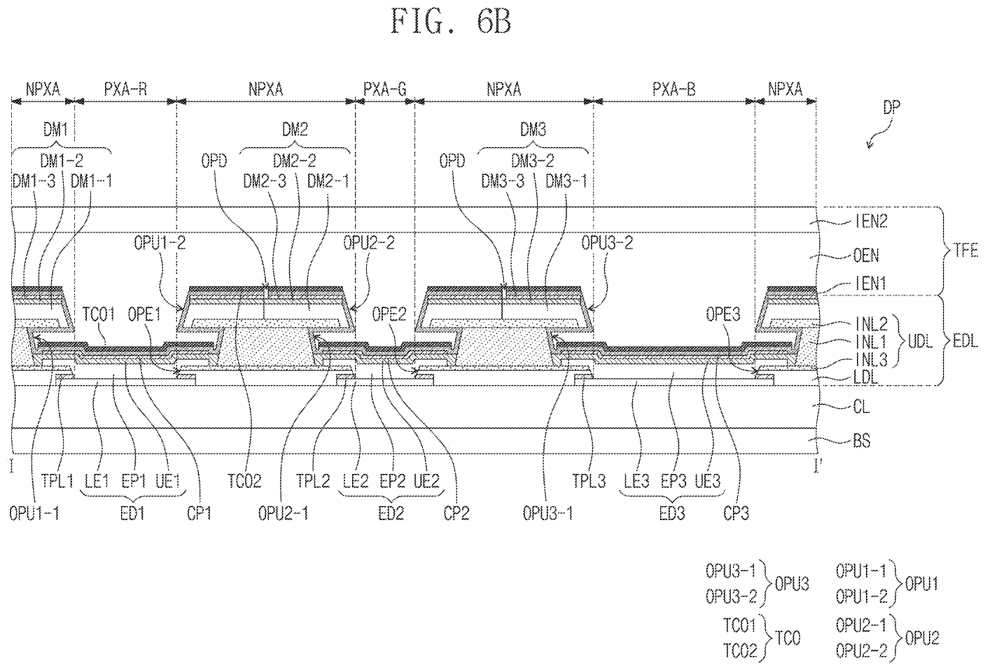

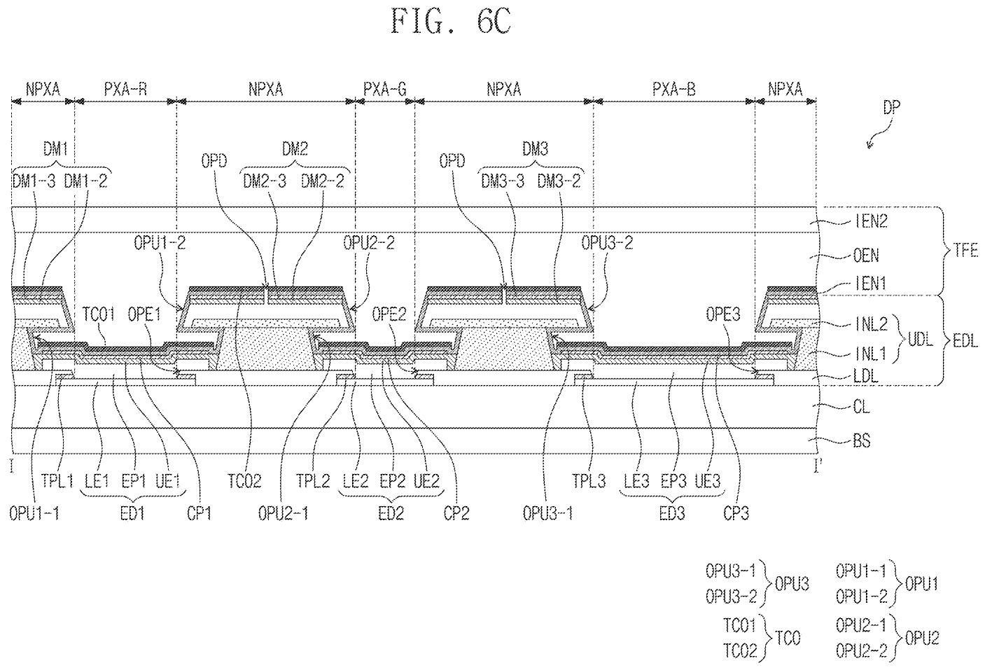

Referring to FIG. 5, the active region AA may include first to third light emitting regions PXA-R, PXA-G and PXA-B, and a non-light emitting region NPXA surrounding the first to third light emitting regions PXA-R, PXA-G and PXA-B. The first to third light emitting regions PXA-R, PXA-G and PXA-B may correspond to regions from which light provided from light emitting elements ED1, ED2 and ED3 (see FIG. 6A) is emitted, respectively.

For convenience of explanation, FIG. 5 illustrates only lower electrodes LE1, LE2 and LE3 among components of the light emitting elements ED1, ED2 and ED3 as an example (see FIG. 6A). The first to third light emitting regions PXA-R, PXA-G and PXA-B may be divided according to colors of light emitted toward the outside of the display module DM (see FIG. 2).

The first to third light emitting regions PXA-R, PXA-G and PXA-B may provide first- to third-color light having different colors, respectively. For example, the first-color light may be red light, the second-color light may be green light, and the third-color light may be blue light. However, examples of the first- to third-color light are not necessarily limited to the foregoing examples.

The first to third light emitting regions PXA-R, PXA-G and PXA-B may be defined as regions of top surfaces of corresponding lower electrodes LE1, LE2 and LE3, which are exposed by corresponding light emitting opening portions OPE1, OPE2 and OPE3, respectively. The light emitting openings OPE1, OPE2 and OPE3 may be defined by a lower pixel defining film LDL (see FIG. 6A), which covers a portion of each of the lower electrodes LE1, LE2 and LE3. This will be described in detail later.

For example, the first light emitting region PXA-R may be defined as a region of the top surface of the first lower electrode LE1, which is exposed by the first light emitting opening portion OPE1. The second light emitting region PXA-G may be defined as a region of the top surface of the second lower electrode LE2, which is exposed by the second light emitting opening portion OPE2. The third light emitting region PXA-B may be defined as a region of the top surface of the third lower electrode LE3, which is exposed by the third light emitting opening portion OPE3.

The non-light emitting region NPXA may define a boundary of each of the first to third light emitting regions PXA-R, PXA-G and PXA-B, and prevent mixture of colors between the first to third light emitting regions PXA-R, PXA-G and PXA-B.

Each of the first to third light emitting regions PXA-R, PXA-G and PXA-B may be provided in plurality to have an arrangement shape (e.g., a set or predetermined arrangement shape) in the active region AA and be repeatedly located.

For example, referring to FIG. 5, the plurality of first light emitting regions PXA-R and the plurality of third light emitting region PXA-B may be arranged alternately with each other in the first direction DR1 and constitute a “first group”. The second light emitting regions PXA-G may be arranged in the first direction DR1 and constitute a “second group”. Each of the “first group” and the “second group” may be provided in plurality, and the “first groups” and the “second groups” may be arranged alternately with each other in the second direction DR2.

One second light emitting region PXA-G may be located apart from one first light emitting region PXA-R or one third light emitting region PXA-B in a fourth direction DR4. The fourth direction DR4 may be defined as a direction between the first direction DR1 and the second direction DR2 on a plane defined by the first direction DR1 and the second direction DR2.

As illustrated in FIG. 5, the first to third light emitting regions PXA-R, PXA-G and PXA-B may be arranged in a PENTILE™ shape. However, the arrangement shape of the first to third light emitting regions PXA-R, PXA-G and PXA-B illustrated in FIG. 5 is an example, and is not limited thereto. The first to third light emitting regions PXA-R, PXA-G and PXA-B may be arranged in various shapes. For example, the first to third light emitting regions PXA-R, PXA-G and PXA-B may be arranged in a stripe shape or in a Diamond Pixel™ shape.

Each of the first to third light emitting regions PXA-R, PXA-G and PXA-B may have various shapes in a plan view. For example, each of the first to third light emitting regions PXA-R, PXA-G and PXA-B may have a shape such as a polygonal, a circular, or an oval shape. FIG. 5 illustrates the first light emitting region PXA-R and the third light emitting region PXA-B, each of which has a square (or rhombus) shape in a plan view, and the second light emitting region PXA-G which has an octagonal shape in a plan view.

The first to third light emitting regions PXA-R, PXA-G and PXA-B may have the same shape, or at least some thereof may have different shapes in a plan view. FIG. 5 illustrates the first light emitting region PXA-R and the third light emitting region PXA-B, which are the same in shape in a plan view, and the second light emitting region PXA-G which is different in shape from the first light emitting region PXA-R and the third light emitting region PXA-B in a plan view.

At least some of the first to third light emitting regions PXA-R, PXA-G and PXA-B may have different areas in a plan view. For example, the area of the first light emitting region PXA-R, which emits red light, may be greater than the area of the second light emitting region PXA-G that emits green light, and may be smaller than the area of the third light emitting region PXA-B that emits blue light. However, a magnitude relationship between the areas of the first to third light emitting regions PXA-R, PXA-G and PXA-B according to the emitted colors is not limited thereto, and may be various according to the design of the display module DM (see FIG. 2). For example, the first to third light emitting regions PXA-R, PXA-G and PXA-B may have the same area in a plan view.

The shape, area, and arrangement of the first to third light emitting regions PXA-R, PXA-G and PXA-B of the display module DM (see FIG. 2) according to some embodiments of the present disclosure in a plan view may be variously designed according to the color of the emitted light or the size or configuration of the display module DM (see FIG. 2), and are not limited to the embodiments illustrated in FIG. 5.

The lower electrodes LE1, LE2 and LE3 may be connected to the driving circuits of the pixel in the circuit layer CL (see FIG. 3) described above through connection contact holes. The connection contact holes may be spaced apart from the light emitting regions PXA-R, PXA-G and PXA-B defined in the lower electrodes LE1, LE2 and LE3, respectively. Alternatively, the connection contact holes may be arranged to have at least portions overlapping the light emitting regions PXA-R, PXA-G and PXA-B defined in the lower electrodes LE1, LE2 and LE3, respectively.

FIGS. 6A to 6C are cross-sectional views of a display panel DP according to some embodiments of the present disclosure taken along line I-I′ in FIG. 5. That is, a cross-sectional view may be of the first to third light emitting regions PXA-R, PXA-G and PXA-B and the non-light emitting region NPXA surrounding the first to third light emitting regions PXA-R, PXA-G and PXA-B in FIG. 5. The first to third light emitting regions PXA-R, PXA-G and PXA-B may correspond to regions from which light provided from the light emitting elements ED1, ED2 and ED3 is emitted, respectively.

Referring to FIGS. 6A to 6C, the display panel DP may include a base layer BS, a circuit layer CL located on the base layer BS, a light emitting element layer EDL located on the circuit layer CL, and an encapsulation layer TFE located on the light emitting element layer EDL. The contents described above with reference to FIG. 3 may similarly apply to the base layer BS and the circuit layer CL in FIGS. 6A to 6C. The light emitting element layer EDL and the encapsulation layer TFE will be described in detail with reference to FIGS. 6A to 6C.

The light emitting element layer EDL may include light emitting elements ED1, ED2 and ED3, protective patterns TPL1, TPL2 and TPL3, a lower pixel defining film LDL, an upper pixel defining film UDL, capping patterns CP1, CP2 and CP3, and dummy patterns DM1, DM2 and DM3.

The light emitting elements ED1, ED2 and ED3 may include a first light emitting element ED1, a second light emitting element ED2, and a third light emitting element ED3. The first light emitting element ED1 may include a first lower electrode LE1, a first light emitting pattern EP1, and a first upper electrode UE1. The second light emitting element ED2 may include a second lower electrode LE2, a second light emitting pattern EP2, and a second upper electrode UE2. The third light emitting element ED3 may include a third lower electrode LE3, a third light emitting pattern EP3, and a third upper electrode UE3.

The first to third lower electrodes LE1, LE2 and LE3 may be provided as a plurality of patterns. Hereinafter, the description will be focused on the first lower electrode LE1, the description of the first lower electrode LE1 may similarly apply to the second lower electrode LE2 and the third lower electrode LE3.

The first lower electrode LE1 may be located on the circuit layer CL. The first lower electrode LE1 may be a (semi-)transmissive electrode or a reflective electrode. The first lower electrode LE1 may have a single-layer structure or a multilayer structure. For example, the first lower electrode LE1 may include a first layer and a second layer.

The first layer may include a metal material. For example, the first layer may be a reflective electrode formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, etc.

The second layer may be located on the first layer. The second layer may include a transparent conductive oxide. For example, the second layer may be a transparent or semi-transparent layer including at least one selected from the group consisting of an indium tin oxide (ITO), an indium zinc oxide (IZO), an indium gallium zinc oxide (IGZO), a zinc oxide (ZnO), an indium oxide (In₂O₃), and an aluminum-doped zinc oxide (AZO). According to some embodiments, the second layer may include a crystallized transparent conductive oxide. For example, the transparent conductive oxide may include a poly-ITO.

According to some embodiments, the first lower electrode LE1 may further include a third layer below the first layer. The third layer may include a transparent conductive oxide. Here, the third layer may include the same material as the second layer, or may include a material different from that of the second layer.

Each of the first to third light emitting patterns EP1, EP2 and EP3 may be located on a corresponding lower electrode among the first to third lower electrodes LE1, LE2 and LE3. For example, the first light emitting pattern EP1 may be located on the first lower electrode LE1, the second light emitting pattern EP2 may be located on the second lower electrode LE2, and the third light emitting pattern EP3 may be located on the third lower electrode LE3. According to some embodiments, the first light emitting pattern EP1 may provide red light, the second light emitting pattern EP2 may provide green light, and the third light emitting pattern EP3 may provide blue light.

Each of the first to third light emitting patterns EP1, EP2 and EP3 may include a light emitting layer including a light emitting material. Each of the first to third light emitting patterns EP1, EP2 and EP3 may further include a hole injection layer and/or a hole transport layer that are located between the light emitting layer and a corresponding lower electrode among the first to third lower electrodes LE1, LE2 and LE3. Each of the first to third light emitting patterns EP1, EP2 and EP3 may further include an electron transport layer and an electron injection layer that are located on the light emitting layer.

The first light emitting pattern EP1, the second light emitting pattern EP2, and the third light emitting pattern EP3 may be located and patterned in a first light emitting opening portion OPE1, a second light emitting opening portion OPE2, and a third light emitting opening portion OPE3, respectively, which are defined by the lower pixel defining film LDL.

In addition, the first light emitting pattern EP1, the second light emitting pattern EP2, and the third light emitting pattern EP3 may be located in a first upper opening portion OPU1, a second upper opening portion OPU2, and a third upper opening portion OPU3, respectively, which are defined by the upper pixel defining film UDL. For example, the first light emitting pattern EP1, the second light emitting pattern EP2, and the third light emitting pattern EP3 may be located in a first-1 upper opening portion OPU1-1, a second-1 upper opening portion OPU2-1, and a third-1 upper opening portion OPU3-1, respectively, which are defined by a first inorganic film INL1 of the upper pixel defining film UDL.

Accordingly, at least portions of a top surface of the lower pixel defining film LDL, which are not covered by the first inorganic film INL1 and exposed by the first-1 upper opening portion OPU1-1, the second-1 upper opening portion OPU2-1, and the third-1 upper opening portion OPU3-1, may be covered by the first light emitting pattern EP1, the second light emitting pattern EP2, and the third light emitting pattern EP3, respectively.

FIG. 6A illustrates that the portions of the top surface of the lower pixel defining film LDL, which are exposed by the first-1 upper opening portion OPU1-1, the second-1 upper opening portion OPU2-1, and the third-1 upper opening portion OPU3-1, are covered. However, embodiments of the present disclosure are not limited thereto, and the entirety of the exposed top surface of the lower pixel defining film LDL may be covered by the first light emitting pattern EP1, the second light emitting pattern EP2, and the third light emitting pattern EP3.

Each of the first to third upper electrodes UE1, UE2 and UE3 may be located on a corresponding light emitting pattern among the first to third light emitting patterns EP1, EP2 and EP3. For example, the first upper electrode UE1 may be located on the first light emitting pattern EP1, the second upper electrode UE2 may be located on the second light emitting pattern EP2, and the third upper electrode UE3 may be located on the third light emitting pattern EP3.

The first upper electrode UE1, the second upper electrode UE2, and the third upper electrode UE3 may be arranged and patterned in the first upper opening portion OPU1, the second upper opening portion OPU2, and the third upper opening portion OPU3, respectively, which are defined by the upper pixel defining film UDL. For example, the first upper electrode UE1, the second upper electrode UE2, and the third upper electrode UE3 may be located in the first-1 upper opening portion OPU1-1, the second-1 upper opening portion OPU2-1, and the third-1 upper opening portion OPU3-1, respectively, which are defined by the first inorganic film INL1 of the upper pixel defining film UDL.

Accordingly, the at least portions of the top surface of the lower pixel defining film LDL, which are not covered by the first inorganic film INL1 and exposed by the first-1 upper opening portion OPU1-1, the second-1 upper opening portion OPU2-1, and the third-1 upper opening portion OPU3-1, respectively, may be covered.

As illustrated in FIG. 6A, the first upper electrode UE1, the second upper electrode UE2, and the third upper electrode UE3 may cover portions of the top surface of the lower pixel defining film LDL, which are exposed by the first-1 upper opening portion OPU1-1, the second-1 upper opening portion OPU2-1, and the third-1 upper opening portion OPU3-1 and are not covered by the first light emitting pattern EP1, the second light emitting pattern EP2, and the third light emitting pattern EP3.

The first upper electrode UE1 may be in contact with at least a portion of a side surface of the upper pixel defining film UDL, which defines the first upper opening portion OPU1. For example, the first upper electrode UE1 may be in contact with at least a portion of a side surface of the first inorganic film INL1, which defines the first-1 upper opening portion OPU1-1.

Accordingly, the first upper electrode UE1 may be electrically connected to the first inorganic film INL1 and receive a bias voltage through the first inorganic film INL1. The foregoing description of the first upper electrode UE1 may similarly apply to the second and third upper electrodes UE2 and UE3.

When an upper electrode is in the form of a common layer overlapping all of first to third light emitting patterns, a lateral leakage current may occur through the common layer. However, as the first to third upper electrodes UE1, UE2 and UE3 according to some embodiments of the present disclosure are spaced apart from each other and provided on the first to third light emitting patterns EP1, EP2 and EP3, respectively, which are spaced apart from each other, the lateral leakage current that may occur in the form of the common layer may be prevented.

As the upper electrodes UE1, UE2 and UE3 are electrically connected to the first inorganic film INL1 having relatively large thickness, the driving resistance of the first to third light emitting patterns EP1, EP2 and EP3 may be reduced to increase emission efficiency and lifetime.

The first protective pattern TPL1 may define a first lower opening portion that exposes a portion of a top surface of the first lower electrode LE1, the second protective pattern TPL2 may define a second lower opening portion that exposes a portion of a top surface of the second lower electrode LE2, and the third protective pattern TPL3 may define a third lower opening portion that exposes a portion of a top surface of the third lower electrode LE3.

The first to third protective patterns TPL1, TPL2 and TPL3 together with the lower pixel defining film LDL may define the first light emitting opening portion OPE1, the second light emitting opening portion OPE2, and the third light emitting opening portion OPE3, which are illustrated in FIG. 6A.

The protective patterns TPL1, TPL2 and TPL3 may be omitted unlike that illustrated in FIG. 6A. In this case, the lower pixel defining film LDL may define the first light emitting opening portion OPE1, the second light emitting opening portion OPE2, and the third light emitting opening portion OPE3 on the first lower electrode LE1, the second lower electrode LE2, and the third lower electrode LE3, respectively.

The protective patterns TPL1, TPL2 and TPL3 may prevent the first to third lower electrodes LE1, LE2 and LE3 from being damaged during an etching process for forming the lower pixel defining film LDL.

The lower pixel defining film LDL may be located on the circuit layer CL. The lower pixel defining film LDL may be formed so as to cover a portion of the top surface of each of the first to third lower electrodes LE1, LE2 and LE3, and define the first to third light emitting opening portions OPE1, OPE2 and OPE3.

When the first to third protective patterns TPL1, TPL2 and TPL3 are located on the top surfaces of the first to third lower electrodes LE1, LE2 and LE3, respectively, as in FIG. 6A, the lower pixel defining film LDL may be located on a top surface of each of the first to third protective patterns TPL1, TPL2 and TPL3.

Accordingly, the first to third protective patterns TPL1, TPL2 and TPL3 together with the lower pixel defining film LDL may define the first to third light emitting opening portions OPE1, OPE2 and OPE3, respectively.

FIG. 6A illustrates that side surfaces of the first to third protective patterns TPL1, TPL2 and TPL3, which define the first to third light emitting opening portions OPE1, OPE2 and OPE3, are more adjacent to centers of the first to third lower electrodes LE1, LE2 and LE3, respectively, than a side surface of the lower pixel defining film LDL in a plan view. However, embodiments of the present disclosure are not limited thereto, and the side surface of the lower pixel defining film LDL may be more adjacent to the center of each of the first to third lower electrodes LE1, LE2 and LE3 than the side surface of each of the first to third protective patterns TPL1, TPL2 and TPL3.

The lower pixel defining film LDL may include an organic insulating material, and may include, for example, a silicon nitride (SiNₓ). The lower pixel defining film LDL may be located between each of the first to third lower electrodes LE1, LE2 and LE3 and the upper pixel defining film UDL and block the upper pixel defining film UDL from being electrically connected to each of the first to third lower electrodes LE1, LE2 and LE3.

The protective patterns TPL1, TPL2 and TPL3 may include a first protective pattern TPL1, a second protective pattern TPL2, and a third protective pattern TPL3. For example, the first protective pattern TPL1 may be located on the top surface of the first lower electrode LE1, the second protective pattern TPL2 may be located on the top surface of the second lower electrode LE2, and the third protective pattern TPL3 may be located on the top surface of the third lower electrode LE3.

The upper pixel defining film UDL may be located on the lower pixel defining film LDL. The first to third upper opening portions OPU1, OPU2 and OPU3 may be defined by the upper pixel defining film UDL.

The upper pixel defining film UDL may include the first inorganic film INL1 and a second inorganic film INL2. The first inorganic film INL1 may be located on the lower pixel defining film LDL, and the second inorganic film INL2 may be located on the first inorganic film INL1. The first inorganic film INL1 may have a thickness larger than a thickness of the second inorganic film INL2.

The second inorganic film INL2 may have a side surface that is more adjacent to the center of each of the first to third lower electrodes LE1, LE2 and LE3 than the side surface of the first inorganic film INL1 in a plan view. A portion of the second inorganic film INL2, which is more adjacent to the center of each of the first to third lower electrodes LE1, LE2 and LE3 than the side surface of the first inorganic film INL1, may be defined as a tip-portion of the upper pixel defining film UDL.

The first-1 upper opening portion OPU1-1, the second-1 upper opening portion OPU2-1, and the third-1 upper opening portion OPU3-1 may be defined by the first inorganic film INL1. A first-2 upper opening portion OPU1-2, a second-2 upper opening portion OPU2-2, and a third-2 upper opening portion OPU3-2 may be defined by the second inorganic film INL2. The first-2 upper opening portion OPU1-2, the second-2 upper opening portion OPU2-2, and the third-2 upper opening portion OPU3-2 may correspond to the first light emitting opening portion OPE1, the second light emitting opening portion OPE2, and the third light emitting opening portion OPE3, respectively.

The areas of the first-1 upper opening portion OPU1-1, the second-1 upper opening portion OPU2-1, and the third-1 upper opening portion OPU3-1 may be greater than the areas of the first-2 upper opening portion OPU1-2, the second-2 upper opening portion OPU2-2, and the third-2 upper opening portion OPU3-2, respectively, in a plan view. The areas of the first-1 upper opening portion OPU1-1, the second-1 upper opening portion OPU2-1, and the third-1 upper opening portion OPU3-1 may be greater than the areas of the first light emitting opening portion OPE1, the second light emitting opening portion OPE2, and the third light emitting opening portion OPE3, respectively, in a plan view.

The first inorganic film INL1 and the second inorganic film INL2 may each include an inorganic material. The first inorganic film INL1 and the second inorganic film INL2 may each include an inorganic insulating film or a conductive metal. The first inorganic film INL1 and the second inorganic film INL2 may each include a conductive metal. For example, the first inorganic film INL1 may include aluminum (Al) or molybdenum (Mo), and the second inorganic film INL2 may include titanium (Ti). However, the material included in each of the first and second inorganic films INL1 and INL2 is not limited thereto. For example, the second inorganic film INL2 may include an insulating material.

In an etching process for forming the upper pixel defining film UDL, the first inorganic film INL1 may have an etch rate higher than an etch rate of the second inorganic film INL2. That is, the first inorganic film INL1 may include a material having higher etch selectivity than that of the second inorganic film INL2.

The second inorganic film INL2 may include a material having a lower reflectance than that of the first inorganic film INL1. As the second inorganic film INL2 constitutes an upper portion of the upper pixel defining film UDL, the reflectance at a top surface of the upper pixel defining film UDL may be reduced to improve display quality of the display panel DP.

The upper pixel defining film UDL may further include a third inorganic film INL3 as illustrated in FIG. 6B. The third inorganic film INL3 may be located on the lower pixel defining film LDL. The foregoing contents of the second inorganic film INL2 may apply to the third inorganic film INL3.

The capping patterns CP1, CP2 and CP3 may include a first capping pattern CP1 located on the first upper electrode UE1, a second capping pattern CP2 located on the second upper electrode UE2, and a third capping pattern CP3 located on the third upper electrode UE3.

The capping patterns CP1, CP2 and CP3 may each include a single layer or multiple layers. Each of the capping patterns CP1, CP2 and CP3 may be an inorganic layer or an organic layer. For example, when the capping patterns CP1, CP2 and CP3 include an inorganic matter, the inorganic matter may include an alkali metal compound such as LiF, an alkaline earth metal compound such as MgF2, SiON, SiNₓ, SiO_{y}, or the like. For example, when the capping patterns CP1, CP2 and CP3 include an organic matter, the organic matter may include α-NPD, NPB, TPD, m-MTDATA, Alq3, CuPc, N4,N4,N4′,N4′-tetra (biphenyl-4-yl) biphenyl-4,4′-diamine (TPD15), 4,4′,4″-tris (carbazol sol-9-yl) triphenylamine (TCTA), or the like, or include an epoxy resin, or acrylate such as methacrylate.

The capping patterns CP1, CP2 and CP3 may each function as a buffer layer that protects the light emitting element ED, etc., located therebelow. The capping patterns CP1, CP2 and CP3 may each have a refractive index of about 1.6 or greater. For example, the refractive index of each of the capping patterns CP1, CP2 and CP3 may be about 1.9. As each of the capping patterns CP1, CP2 and CP3 has the refractive index of about 1.9, light extraction efficiency, etc., of the light emitting element layer EDL may be improved.

The dummy patterns DM1, DM2 and DM3 may include a first dummy pattern DM1 surrounding the first light emitting element ED1, a second dummy pattern DM2 surrounding the second light emitting element ED2, and a third dummy pattern DM3 surrounding the third light emitting element ED3 in a plan view.

The first dummy pattern DM1 may include a first-1 dummy pattern DM1-1, a first-2 dummy pattern DM1-2, and a first-3 dummy pattern DM1-3. The first-1 dummy pattern DM1-1 may include the same light emitting material as the light emitting element ED1. The first-2 dummy pattern DM1-2 may include the same electrode material as the first upper electrode UE1. The first-3 dummy pattern DM1-3 may include the same capping material as the first capping pattern CP1.

The second dummy pattern DM2 may include a second-1 dummy pattern DM2-1, a second-2 dummy pattern DM2-2, and a second-3 dummy pattern DM2-3. The second-1 dummy pattern DM2-1 may include the same light emitting material as the second light emitting pattern EP2. The second-2 dummy pattern DM2-2 may include the same electrode material as the second upper electrode UE2. The second-3 dummy pattern DM2-3 may include the same capping material as the second capping pattern CP2.

The third dummy pattern DM3 may include a third-1 dummy pattern DM3-1, a third-2 dummy pattern DM3-2, and a third-3 dummy pattern DM3-3. The third-1 dummy pattern DM3-1 may include the same light emitting material as the third light emitting pattern EP3. The third-2 dummy pattern DM3-2 may include the same electrode material as the third upper electrode UE3. The third-3 dummy pattern DM3-3 may include the same capping material as the third capping pattern CP3.

At least some of the dummy patterns DM1, DM2 and DM3 may be spaced apart from each other on the upper pixel defining film UDL. For example, the first-2 dummy pattern DM1-2, the second-2 dummy pattern DM2-2, and the third-2 dummy pattern DM3-2 may be spaced apart from each other on the first-1 dummy pattern DM1-1, the second-1 dummy pattern DM2-1, and the third-1 dummy pattern DM3-1, respectively. The first-3 dummy pattern DM1-3, the second-3 dummy pattern DM2-3, and the third-3 dummy pattern DM3-3 may be spaced apart from each other on the first-2 dummy pattern DM1-2, the second-2 dummy pattern DM2-2, and the third-2 dummy pattern DM3-2, respectively.

As the at least some of the dummy patterns DM1, DM2 and DM3 are spaced apart from each other, the first dummy pattern DM1 and the second dummy pattern DM2, the second dummy pattern DM2 and the third dummy pattern DM3, or the first dummy pattern DM1 and the third dummy pattern DM3 may define a dummy opening portion OPD. The dummy opening portion OPD may be filled with an organic encapsulation film OEN.

For example, as illustrated in FIG. 6A, only some of the dummy patterns DM1, DM2 and DM3 may be spaced apart from each other. That is, the first-3 dummy pattern DM1-3, the second-3 dummy pattern DM2-3, and the third-3 dummy pattern DM3-3 may be spaced apart from each other, the first-1 dummy pattern DM1-1, the second-1 dummy pattern DM2-1, and the third-1 dummy pattern DM3-1 may be arranged to be in contact with each other, and the first-2 dummy pattern DM1-2, the second-2 dummy pattern DM2-2, and the third-2 dummy pattern DM3-2 may be arranged to be in contact with each other.

Alternatively, as illustrated in FIG. 6C, the first-2 dummy pattern DM1-2, the second-2 dummy pattern DM2-2, and the third-2 dummy pattern DM3-2 may be spaced apart from each other, and the first-3 dummy pattern DM1-3, the second-3 dummy pattern DM2-3, and the third-3 dummy pattern DM3-3 may be spaced apart from each other. In this case, spaces, in which the first-1 dummy pattern DM1-1, the second-1 dummy pattern DM2-1, and the third-1 dummy pattern DM3-1 are located in FIG. 6A, may be filled with the organic encapsulation film OEN.

The encapsulation layer TFE may cover the light emitting elements ED1, ED2 and ED3. The encapsulation layer TFE may seal the light emitting element layer EDL. The encapsulation layer TFE may be a thin film encapsulation layer. The encapsulation layer TFE may have a single-layer structure or a structure in which a plurality of layers are stacked. The encapsulation layer TFE may include at least one insulation layer.

The encapsulation layer TFE may include at least one inorganic film and at least one organic film. For example, the encapsulation layer TFE may include a first inorganic encapsulation film IEN1, the organic encapsulation film OEN, and a second inorganic encapsulation film IEN2. However, the layers constituting the encapsulation layer TFE are not limited thereto.

The first inorganic encapsulation film IEN1 and the second inorganic encapsulation film IEN2 protect the light emitting element layer EDL from moisture and oxygen. Each of the first inorganic encapsulation film IEN1 and the second inorganic encapsulation film IEN2 may include a silicon nitride, a silicon oxynitride, a silicon oxide, a titanium oxide, an aluminum oxide layer, or the like, and is not particularly limited thereto.

The organic encapsulation film OEN protects the light emitting element layer EDL from foreign matters such as dust particles. The organic encapsulation film OEN may include an acrylic compound, an epoxy-based compound, etc. The organic encapsulation film OEN may include a photopolymerizable organic matter, and is not particularly limited.

The encapsulation layer TFE according to some embodiments of the present disclosure may further include a transparent conductive oxide film TCO. The transparent conductive oxide film TCO may include a transparent conductive oxide. The transparent conductive oxide film TCO may have a thickness of about 500 Å to about 2000 Å.

The transparent conductive oxide film TCO may include a first transparent conductive oxide film TCO1 and a second transparent conductive oxide film TCO2. The first transparent conductive oxide film TCO1 and the second transparent conductive oxide film TCO2 may be identical except that the former is located on each of the emitting patterns EP1, EP2 and EP3 and the latter is located on each of the dummy patterns DM1, DM2 and DM3. The thickness of the first transparent conductive oxide film TCO1 and the thickness of the second transparent conductive oxide film TCO2 may be equal to each other.

For example, the second transparent conductive oxide films TCO2 may be spaced apart from each other on the dummy patterns DM1, DM2 and DM3, respectively. The second transparent conductive oxide films TCO2, which are spaced apart from each other, may define a transparent conductive oxide film opening portion, and the transparent conductive oxide film opening portion may correspond to the dummy opening portion OPD. The dummy opening portion OPD and the transparent conductive oxide film opening portion corresponding thereto may be filled with and sealed by the organic encapsulation film OEN.

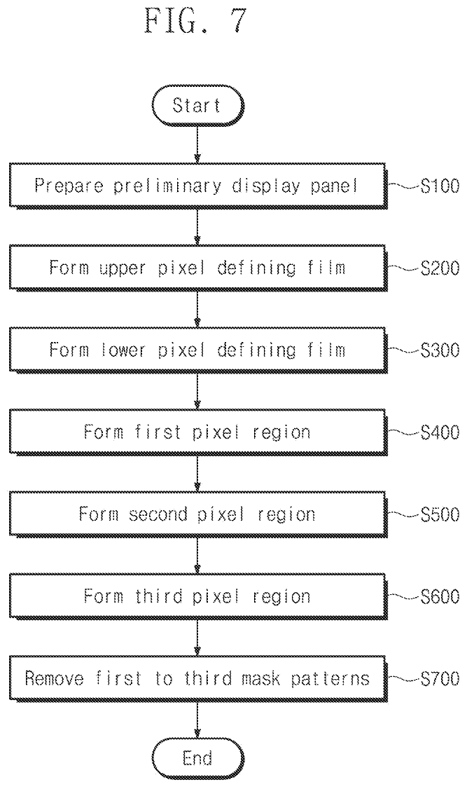

FIG. 7 is a flowchart of a method for manufacturing the display panel DP (see FIG. 6A) according to some embodiments of the present disclosure. The contents of the display panel DP described with reference to FIGS. 1 to 6C may similarly apply to FIG. 7 and the following drawings.

The method for manufacturing the display panel DP (see FIG. 6A) according to some embodiments of the present disclosure may include preparing a preliminary display panel (S100), forming an upper pixel defining film UDL (S200), forming a lower pixel defining film LDL (S300), forming a first pixel region (S400), forming a second pixel region (S500), forming a third pixel region (S600), and removing first to third mask patterns MP1, MP2 and MP3 (S700). The respective operations will be described in detail with reference to the drawings.

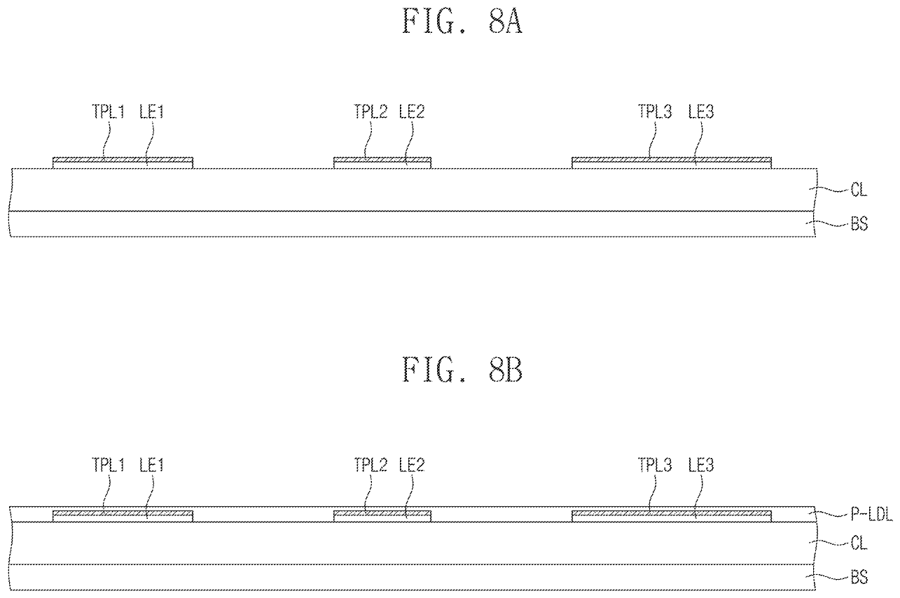

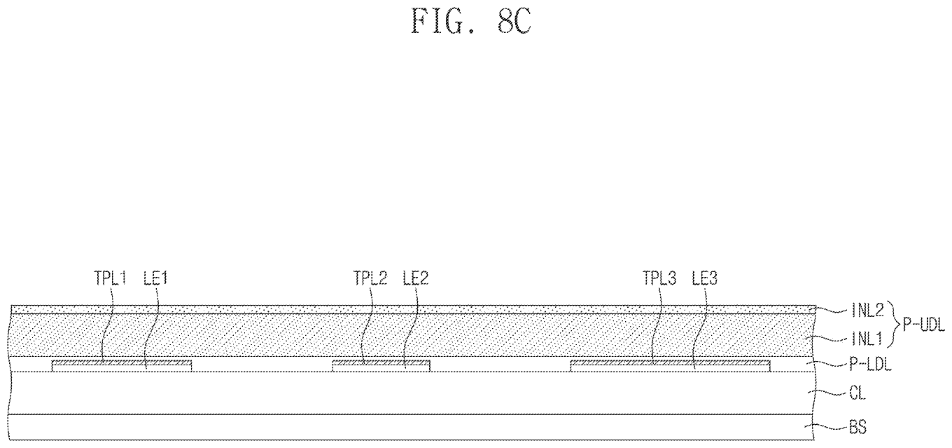

FIGS. 8A to 8C are cross-sectional views illustrating some operations, respectively, of the method for manufacturing the display panel DP (see FIG. 6A) according to some embodiments of the present disclosure. FIGS. 8A to 8C are cross-20 sectional views, each of which illustrates an example of the preparing of the preliminary display panel (S100) (see FIG. 7).

Referring to FIG. 8A, the preparing of the preliminary display panel (S100) (see FIG. 7) may include patterning first to third lower electrodes LE1, LE2 and LE3 and first to third protective patterns TPL1, TPL2 and TPL3 on a base layer BS and a circuit layer CL. For example, the first to third protective patterns TPL1, TPL2 and TPL3 may be formed on the first to third lower electrodes LE1, LE2 and LE3, respectively.

Referring to FIG. 8B, the preparing of the preliminary display panel (S100) (see FIG. 7) may include forming a preliminary lower pixel defining film P-LDL. The preliminary lower pixel defining film P-LDL may be formed on the circuit layer CL and cover the first to third lower electrodes LE1, LE2 and LE3 and the first to third protective patterns TPL1, TPL2 and TPL3.

Referring to FIG. 8C, the preparing of the preliminary display panel (S100) (see FIG. 7) may include forming a preliminary upper pixel defining film P-UDL. The preliminary upper pixel defining film P-UDL may be formed on the preliminary lower pixel defining film P-LDL. The preliminary upper pixel defining film P-UDL may include a first inorganic film INL1 and a second inorganic film INL2 formed on the first inorganic film INL1.

When the upper pixel defining film UDL (see FIG. 6B) having a three-layer structure is formed, forming the third inorganic film INL3 (see FIG. 6B) on the preliminary lower pixel defining film P-LDL may be further included before the forming of the first inorganic film INL1.

The operations described with reference to FIGS. 8A to 8C may be performed to prepare the preliminary display panel including the base layer BS, the circuit layer CL, the first to third lower electrodes LE1, LE2 and LE3, the first to third protective patterns TPL1, TPL2 and TPL3, the preliminary lower pixel defining film P-LDL, and the preliminary upper pixel defining film P-UDL.

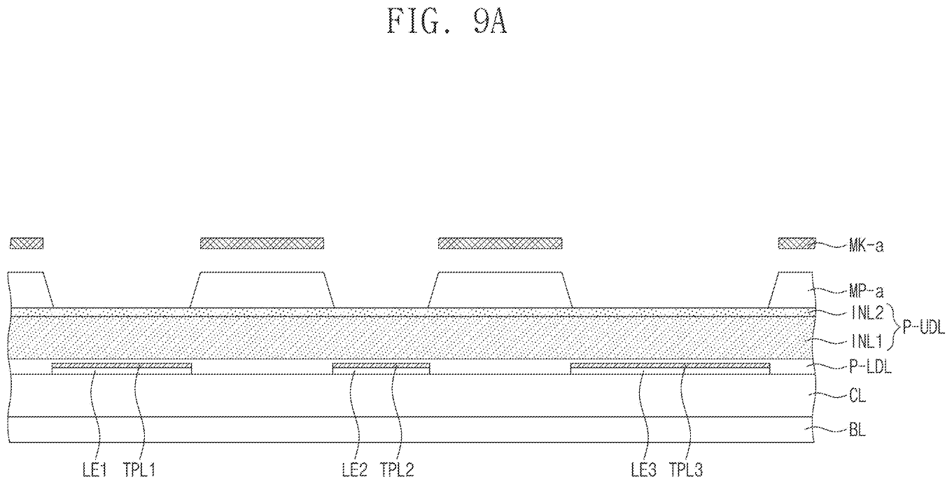

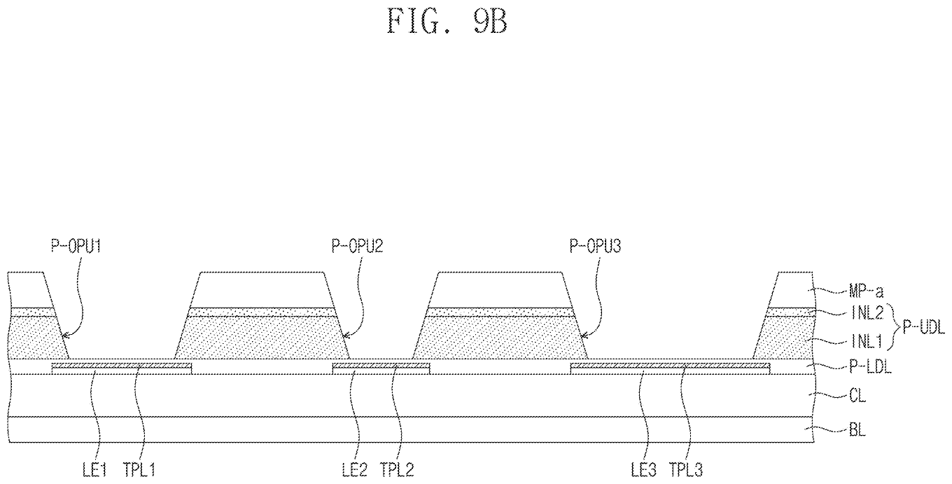

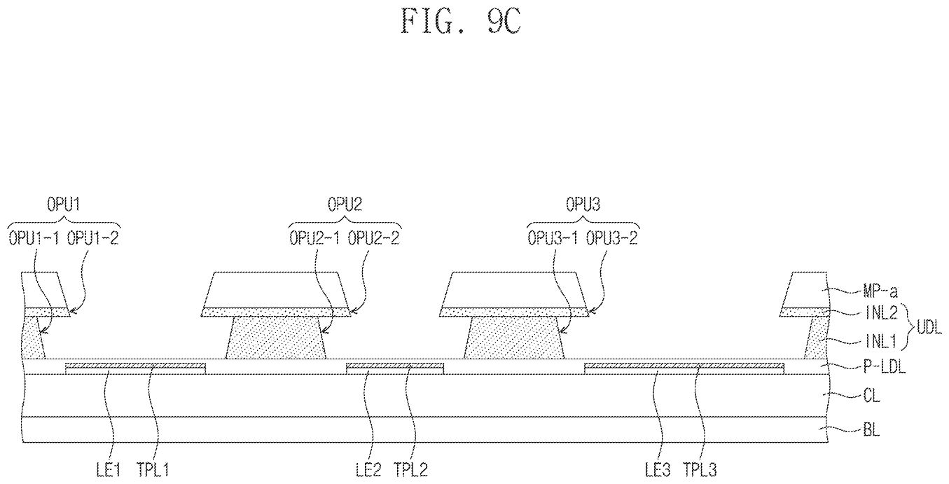

FIGS. 9A to 9C are cross-sectional views illustrating some operations, respectively, of the method for manufacturing the display panel DP (see FIG. 6A) according to some embodiments of the present disclosure. FIGS. 9A to 9C are cross-sectional views, each of which illustrates an example of the forming of an upper pixel defining film UDL (see FIG. 9C) (S200) (see FIG. 7).

Referring to FIG. 9A, the forming of the upper pixel defining film UDL (see FIG. 9C) (S200) (see FIG. 7) may include forming a photomask pattern MP-a on the preliminary display panel formed in the preparing of the preliminary display panel (S100) (see FIG. 7). The photomask pattern MP-a may be formed by using a photomask MK-a having opening portions that are defined in regions corresponding to the first to third lower electrodes LE1, LE2 and LE3, respectively. The photomask pattern MP-a may be formed by using the photomask MK-a through exposure and development processes.

Referring to FIG. 9B, the forming of the upper pixel defining film UDL (see FIG. 9C) (S200) (see FIG. 7) may include forming first to third preliminary upper opening portions P-OPU1, P-OPU2 and P-OPU3 from the preliminary upper pixel defining film P-UDL by etching. For example, the first inorganic film INL1 and the second inorganic film INL2 may be dry etched by using the photomask pattern MP-a as a mask to form the first to third preliminary upper opening portions P-OPU1, P-OPU2 and P-OPU3.

Referring to FIG. 9C, the forming of the upper pixel defining film UDL (S200) (see FIG. 7) may include forming first to third upper opening portions OPU1, OPU2 and OPU3 by etching. For example, the first inorganic film INL1 and the second inorganic film INL2 may be wet etched by using the photomask pattern MP-a as a mask. An etching solution, which has a higher etch rate of the first inorganic film INL1 than an etch rate of the second inorganic film INL2, may be used to perform wet etching so that the first inorganic film INL1 is mainly etched.

Accordingly, a side surface of the second inorganic film INL2 may be formed to be more adjacent to a center of each of the first to third lower electrodes LE1, LE2 and LE3 than a side surface of the first inorganic film INL1 in a plan view. A portion of the second inorganic film INL2, which is more adjacent to the center of each of the first to third lower electrodes LE1, LE2 and LE3 than the side surface of the first inorganic film INL1, may be formed as a tip-portion of the upper pixel defining film UDL.

The areas of a first-1 upper opening portion OPU1-1, a second-1 upper opening portion OPU2-1, and a third-1 upper opening portion OPU3-1, which are defined by the first inorganic film INL1, may be formed to be greater than the areas of a first-2 upper opening portion OPU1-2, a second-2 upper opening portion OPU2-2, and a third-2 upper opening portion OPU3-2, respectively, which are defined by the second inorganic film INL2.

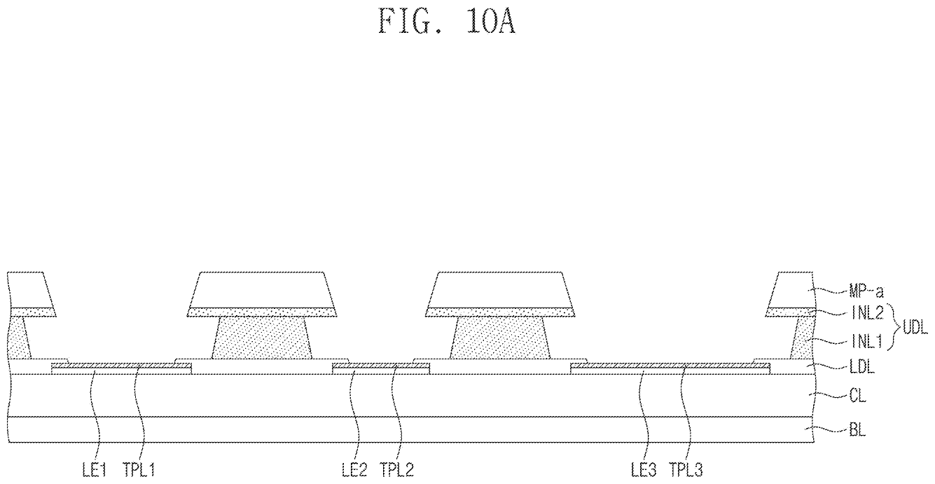

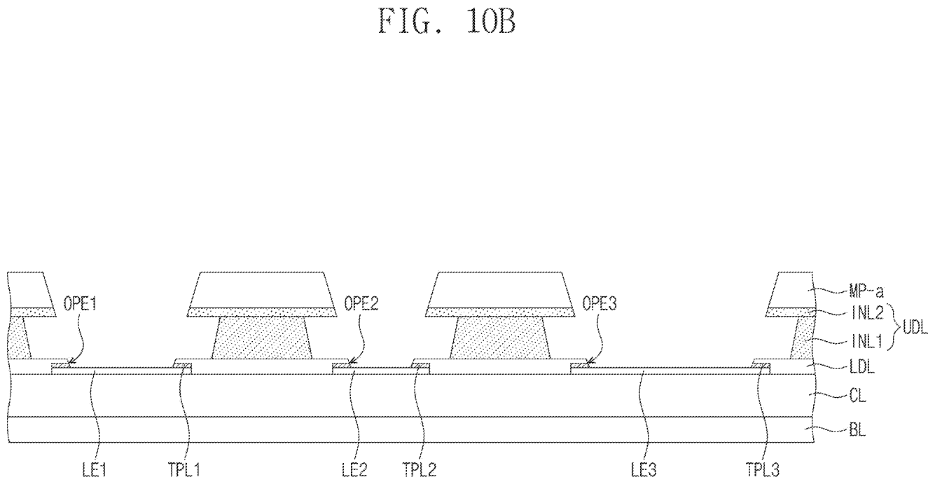

FIGS. 10A and 10B are cross-sectional views illustrating some operations, respectively, of the method for manufacturing the display panel DP (see FIG. 6A) according to some embodiments of the present disclosure. FIGS. 10A and 10B are cross-sectional views, each of which illustrates an example of the forming of a lower pixel defining film LDL (S300) (see FIG. 7).

Referring to FIG. 10A, the forming of the lower pixel defining film LDL (S300) (see FIG. 7) may include etching the preliminary lower pixel defining film P-LDL through an etching process. The preliminary lower pixel defining film P-LDL may be dry etched by using the photomask pattern MP-a as a mask and accordingly, the first to third protective patterns TPL1, TPL2 and TPL3 may be exposed.

The first to third lower electrodes LE1, LE2 and LE3 may be protected by the first to third protective patterns TPL1, TPL2 and TPL3, respectively, to prevent the first to third lower electrodes LE1, LE2 and LE3 from being damaged during the dry etching.

Referring to FIG. 10B, the forming of the lower pixel defining film LDL (S300) (see FIG. 7) may include forming first to third light emitting opening portions OPE1, OPE2 and OPE3 by etching. The first to third protective patterns TPL1, TPL2 and TPL3 may be wet etched.

In the wet etching, an etching solution, which has a higher etch rate of the first to third protective patterns TPL1, TPL2 and TPL3 than an etch rate of the first to third lower electrodes LE1, LE2 and LE3, may be used. Accordingly, the first to third lower electrodes LE1, LE2 and LE3 may not be damaged during the wet etching.

Accordingly, a partial region of each of the first to third lower electrodes LE1, LE2 and LE3 is exposed without being covered by the lower pixel defining film LDL and each of the first to third protective patterns TPL1, TPL2 and TPL3. That is, each of the first to third light emitting opening portions OPE1, OPE2 and OPE3 may be defined by the lower pixel defining film LDL and each of the first to third protective patterns TPL1, TPL2 and TPL3.

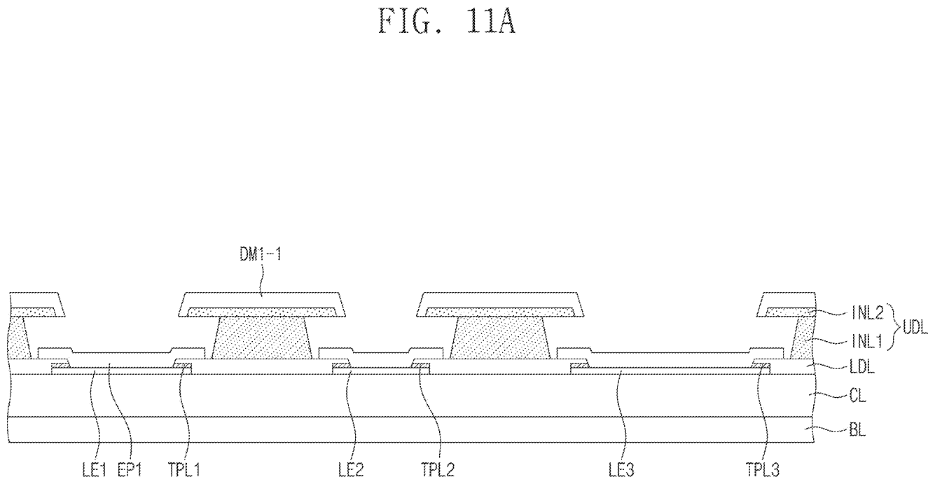

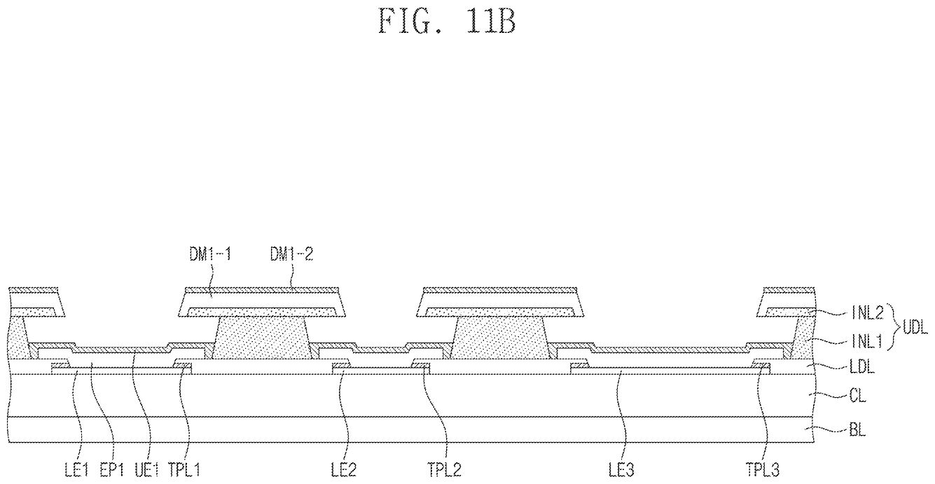

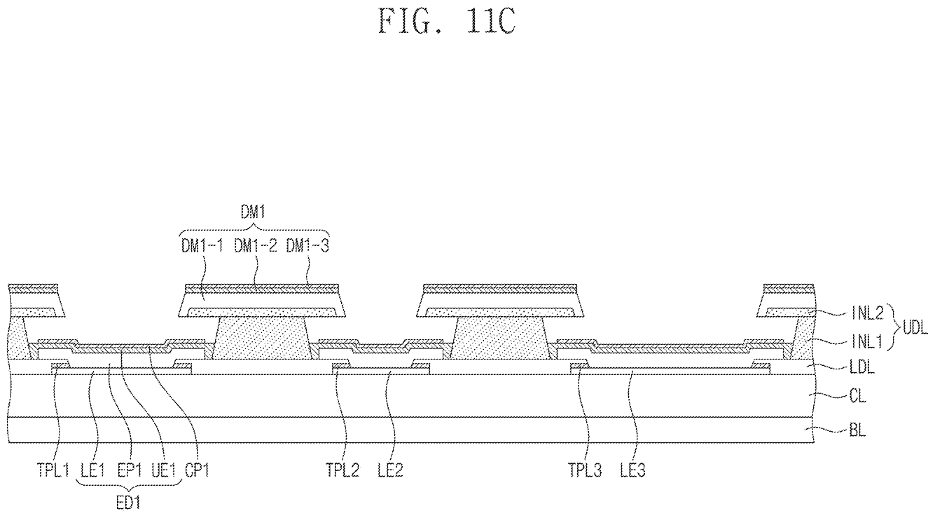

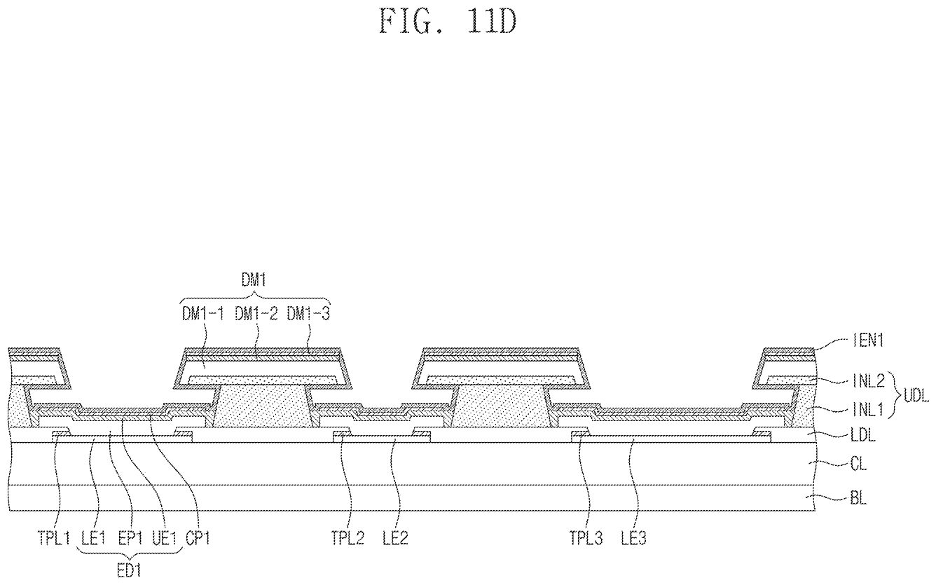

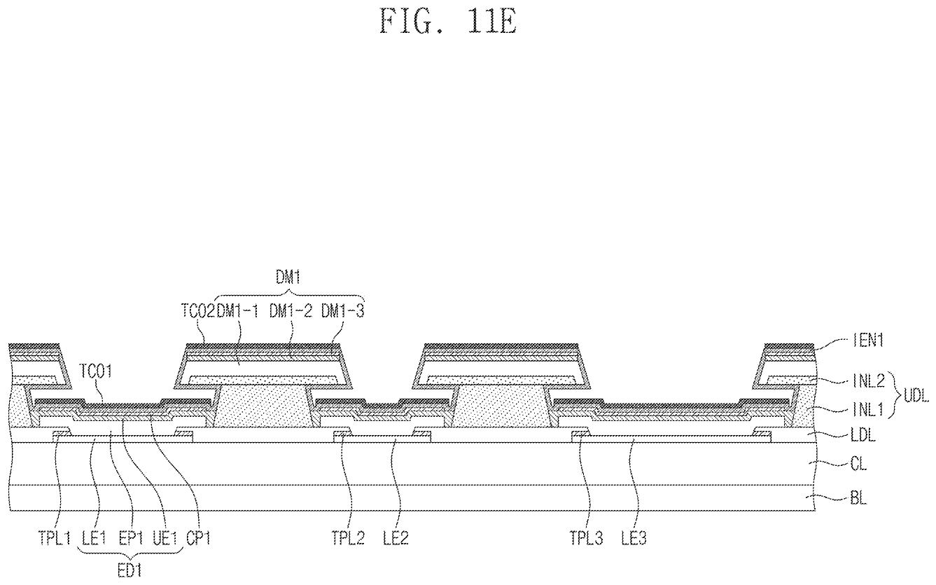

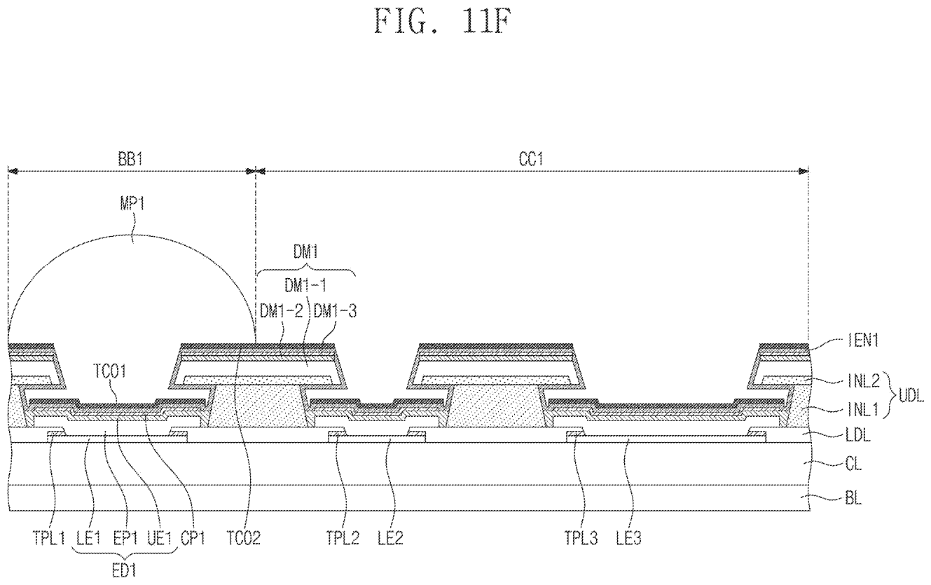

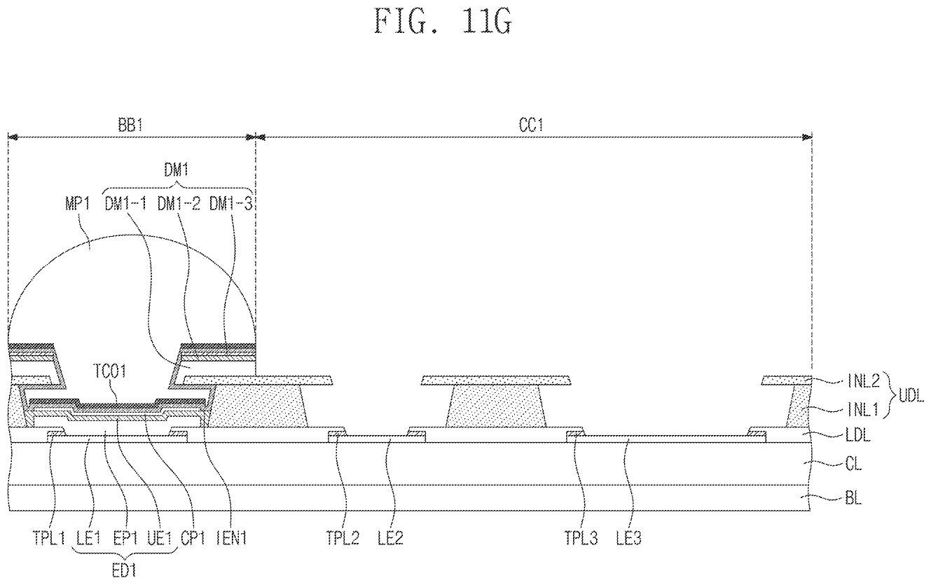

FIGS. 11A to 11G are cross-sectional views illustrating some operations, respectively, of the method for manufacturing the display panel DP (see FIG. 6A) according to some embodiments of the present disclosure. FIGS. 11A to 11G are cross-sectional views, each of which illustrates an example of the forming of the first pixel region (S400) (see FIG. 7).

Referring to FIG. 11A, the forming of the first pixel region (S400) (see FIG. 7) may include forming a first light emitting pattern EP1 and a first-1 dummy pattern DM1-1. The first light emitting pattern EP1 and the first-1 dummy pattern DM1-1A may be formed by depositing a first light emitting material on the first to third lower electrodes LE1, LE2 and LE3 and the upper pixel defining film UDL. The photomask pattern MP-a (see FIG. 10B) is removed and then, the first light emitting material may be deposited by thermal evaporation.

For example, the first light emitting pattern EP1 may mean a light emitting material formed on the first lower electrode LE1. The first-1 dummy pattern DM1-1 may mean a light emitting material formed at a position other than the position of the first light emitting pattern EP1. For example, the first-1 dummy pattern DM1-1 may mean a light emitting material formed on each of the upper pixel defining film UDL, the second lower electrode LE2, and the third lower electrode LE3.

Referring to FIG. 11B, the forming of the first pixel region (S400) (see FIG. 7) may include forming a first upper electrode UE1 and a first-2 dummy pattern DM1-2. The first upper electrode UE1 and the first-2 dummy pattern DM1-2 may be formed on the first light emitting pattern EP1 and the first-1 dummy pattern DM1-1, respectively. The first upper electrode UE1 and the first-2 dummy pattern DM1-2 may be formed by sputtering.

For example, the first upper electrode UE1 may be formed on the first light emitting pattern EP1. The first-2 dummy pattern DM1-2 may be formed on the first-1 dummy pattern DM1-1. Here, the first upper electrode UE1 may be formed so as to be in contact with and electrically connected to at least a portion of a side surface of the upper pixel defining film UDL.

Referring to FIG. 11C, the forming of the first pixel region (S400) (see FIG. 7) may include forming a first capping pattern CP1 and a first-3 dummy pattern DM1-3. The first capping pattern CP1 and the first-3 dummy pattern DM1-3 may be formed on the first upper electrode UE1 and the first-2 dummy pattern DM1-2, respectively. The forming of the first capping pattern CP1 and the first-3 dummy pattern DM1-3 may be omitted.

The dummy pattern DM1 may be defined as a portion other than the patterns formed inside the first-1 upper opening portion OPU1-1 (see FIG. 9C). For example, the first-1 to first-3 dummy patterns DM1-1, DM1-2 and DM1-3 may be defined as a first dummy pattern DM1. When the first-3 dummy pattern DM1-3 is omitted, the first-1 and first-2 dummy patterns DM1-1 and DM1-2 may be defined as the first dummy pattern DM1.

Referring to FIG. 11D, the forming of the first pixel region (S400) (see FIG. 7) may include forming a first inorganic encapsulation film IEN1. The first inorganic encapsulation film IEN1 may be formed so as to cover the first upper electrode UE1, the first dummy pattern DM1, and the exposed upper pixel defining film UDL. The first inorganic encapsulation film IEN1 may be formed through chemical vapor deposition.

Referring to FIG. 11E, the forming of the first pixel region (S400) (see FIG. 7) may include forming transparent conductive oxide films TCO1 and TCO2. The transparent conductive oxide films TCO1 and TCO2 may be formed on the first inorganic encapsulation film IEN1.

For example, a first transparent conductive oxide film TCO1 may be formed on the first inorganic encapsulation film IEN1 corresponding to the region in which the first light emitting pattern EP1 is formed. A second transparent conductive oxide film TCO2 may be formed on the first inorganic encapsulation film IEN1 corresponding to the region in which the first dummy pattern DM1 is formed. That is, the transparent conductive oxide films TCO1 and TCO2 may include the first transparent conductive oxide film TCO1 and the second transparent conductive oxide film TCO2, and the first transparent conductive oxide film TCO1 and the second transparent conductive oxide film TCO2 may mean the same material but be formed at different positions.

Referring to FIGS. 11F and 11G together, the forming of the first pixel region (S400) (see FIG. 7) may include first removing. The first removing may include forming the first mask pattern MP1 on a first region BB1, and removing the second transparent conductive oxide film TCO2, the first inorganic encapsulation film IEN1, and the first dummy pattern DM1 of a first removal region CC1.

FIG. 11F may be a view illustrating an example of the forming of the first mask pattern MP1 on the first region BB1. Referring to FIG. 11F, the first region BB1 may mean a region overlapping the first light emitting pattern EP1 and a portion of the upper pixel defining film UDL, which surrounds the first light emitting pattern EP1, in a plan view. The first mask pattern MP1 may be formed on the first region BB1 through exposure and development processes. The first mask pattern MP1 may be formed with high resolution and accordingly, a high resolution of pixels may be achieved.

FIG. 11G may be a view illustrating an example of the removing of the second transparent conductive oxide film TCO2, the first inorganic encapsulation film IEN1, and the first dummy pattern DM1 of the first removal region CC1. Referring to FIG. 11G, the first removal region CC1 may mean a region other than the first region BB1 in a plan view.

For example, the second transparent conductive oxide film TCO2 of the first removal region CC1 may be removed by wet etching. The first inorganic encapsulation film IEN1 and the first dummy pattern DM1 of the first removal region CC1 may be removed by dry etching. That is, the patterns formed in the first region BB1 may be maintained by the first mask pattern MP1, and only the patterns formed in the first removal region CC1 may be removed.

According to some embodiments of the present disclosure, the patterns formed in the first region BB1 may be protected by the first mask pattern MP1 in the first pixel region. The first mask pattern MP1 may be formed with high resolution and thus, more precise pixel patterning may be achieved. For example, patterning of pixels having a high resolution of about 1000 ppi or greater may be achieved.

According to some embodiments of the present disclosure, a lift-off process is not used in order to remove the patterns formed in the first removal region CC1. Thus, usage of a solution, resin, etc., which are required for the lift-off process, may be omitted. That is, material costs may be reduced, and damage of light emitting patterns, which is caused by the solution, resin, etc., during the lift-off process, may be prevented.

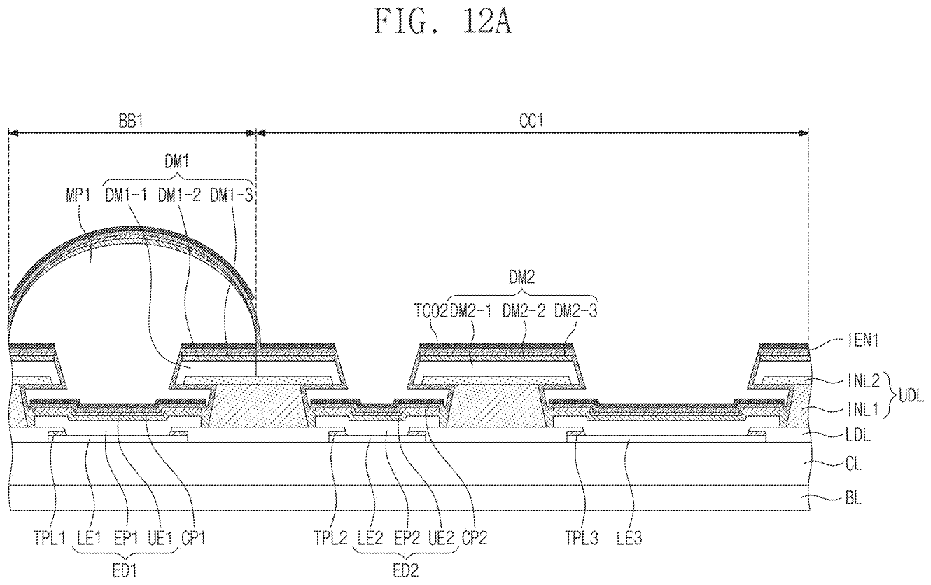

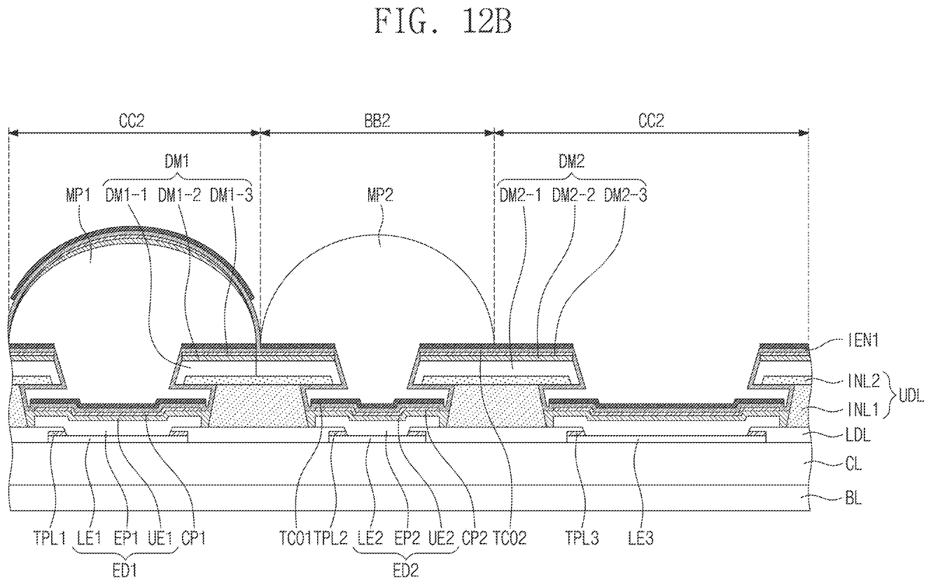

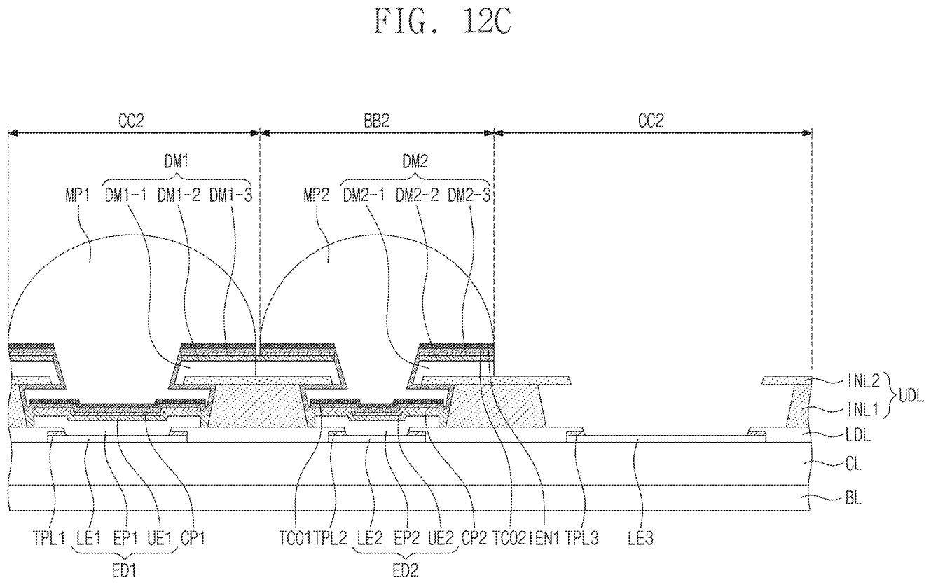

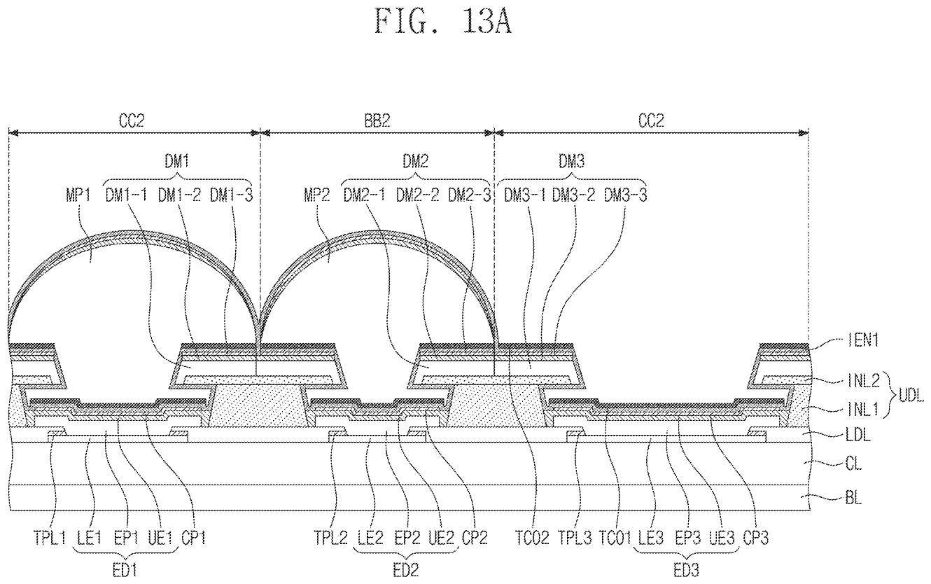

FIGS. 12A to 12C are cross-sectional views illustrating some operations, respectively, of the method for manufacturing the display panel DP (see FIG. 6A) according to some embodiments of the present disclosure. FIGS. 12A to 12C are cross-sectional views, each of which illustrates an example of the forming of the second pixel region (S500) (see FIG. 7). The foregoing contents of the forming of the first pixel region (S400) (see FIG. 7) may correspond and apply to the forming of the second pixel region (S500) (see FIG. 7).

Referring to FIG. 12A, the forming of the second pixel region (S500) (see FIG. 7) may include depositing a second light emitting material on the first region BB1 and the first removal region CC1 to form a second light emitting pattern EP2 and a second-1 dummy pattern DM2-1.

The forming of the second pixel region (S500) (see FIG. 7) may include forming a second upper electrode UE2 and a second-2 dummy pattern DM2-2 on the second light emitting pattern EP2 and the second-1 dummy pattern DM2-1, respectively, so as to be in contact with at least a portion of the side surface of the upper pixel defining film UDL.

The forming of the second pixel region (S500) (see FIG. 7) may include forming a second capping pattern CP2 and a second-3 dummy pattern DM2-3 on the second upper electrode UE2 and the second-2 dummy pattern DM2-2, respectively.

The forming of the second capping pattern CP2 and the second-3 dummy pattern DM2-3 may be omitted.

The dummy pattern DM2 may be defined as a portion other than the patterns formed inside the second-1 upper opening portion OPU2-1 (see FIG. 9C). For example, the second-1 to second-3 dummy patterns DM2-1. DM2-2 and DM2-3 may be defined as a second dummy pattern DM2. When the second-3 dummy pattern DM2-3 is omitted, the second-1 and second-2 dummy patterns DM2-1 and DM2-2 may be defined as the second dummy pattern DM2.

Accordingly, the first dummy pattern DM1 and the second dummy pattern DM2 may be formed on the upper pixel defining film UDL located between the first light emitting element ED1 and the second light emitting element ED2. For example, the first dummy pattern DM1 may be located at a position adjacent to the first light emitting element ED1, and the second dummy pattern DM2 may be formed at a position adjacent to the second light emitting element ED2.

The forming of the second pixel region (S500) (see FIG. 7) may include forming the first inorganic encapsulation film IEN1 so as to cover the second upper electrode UE2, the second dummy pattern DM2, and the upper pixel defining film UDL.

The forming of the second pixel region (S500) (see FIG. 7) may include forming the transparent conductive oxide films TCO1 and TCO2 on the first inorganic encapsulation film IEN1.

Referring to FIG. 12B, the forming of the second pixel region (S500) (see FIG. 7) may include forming the second mask pattern MP2 on a second region BB2. The second region BB2 may mean a region overlapping the second light emitting pattern EP2 and a portion of the upper pixel defining film UDL, which surrounds the second light emitting pattern EP2, in a plan view.

Referring to FIG. 12C, the forming of the second pixel region (S500) (see FIG. 7) may include second removing the second transparent conductive oxide film TCO2, the first inorganic encapsulation film IEN1, and the second dummy pattern DM2 of a second removal region CC2. The second removal region CC2 may mean a region other than the second region BB2.

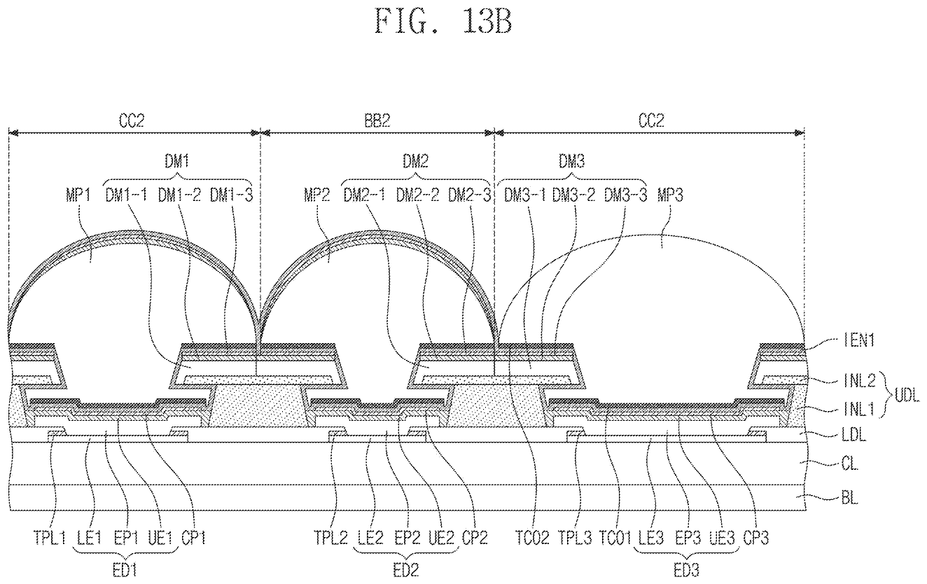

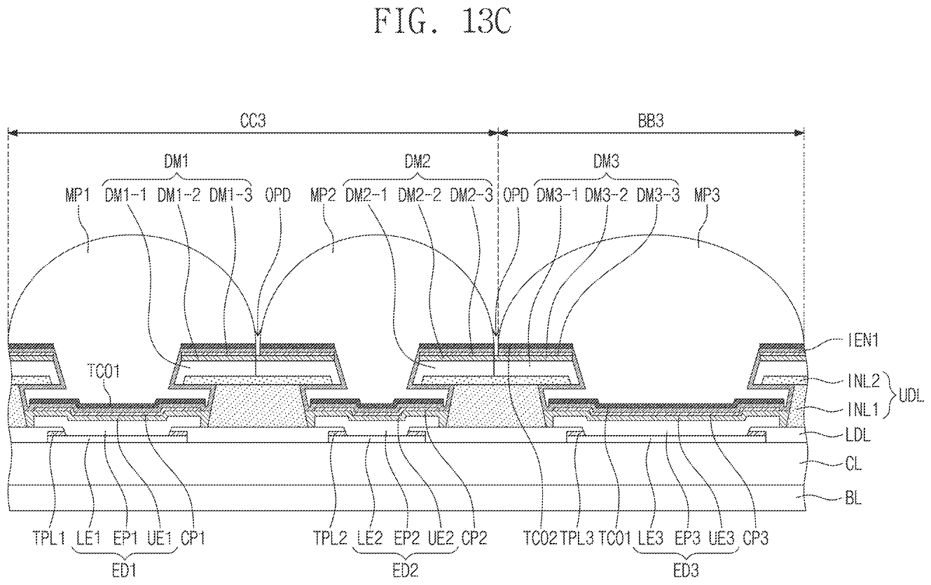

Accordingly, at least portions of the first dummy pattern DM1 and the second dummy pattern DM2 may be formed to be spaced apart from each other on the upper pixel defining film UDL located between the first light emitting element ED1 and the second light emitting element ED2. An opening portion formed by spacing the portions apart from each other may be defined as a dummy opening portion OPD (see FIG. 13C).

In the second removal region CC2, a portion of the second dummy pattern DM2, which is located between the first mask pattern MP1 and the second mask pattern MP2, may not be removed when viewed in a plan view. For example, as illustrated in FIG. 12C, the second-1 dummy pattern DM2-1 and the second-2 dummy pattern DM2-2 of the second dummy pattern DM2 may be remained without being removed.

FIGS. 13A to 13C are cross-sectional views illustrating some operations, respectively, of the method for manufacturing the display panel DP (see FIG. 6A) according to some embodiments of the present disclosure. FIGS. 13A to 13C are cross-sectional views, each of which illustrates an example of the forming of the third pixel region (S600) (see FIG. 7). The foregoing contents of the forming of the first pixel region (S400) (see FIG. 7) may correspond and apply to the forming of the third pixel region (S600) (see FIG. 7).

Referring to FIG. 13A, the forming of the third pixel region (S600) (see FIG. 7) may include depositing a third light emitting material on the second region BB2 and the second removal region CC2 to form a third light emitting pattern EP3 and a third-1 dummy pattern DM3-1.

The forming of the third pixel region (S600) (see FIG. 7) may include forming a third upper electrode UE3 and a third-2 dummy pattern DM3-2 on the third light emitting pattern EP3 and the third-1 dummy pattern DM3-1, respectively, so as to be in contact with at least a portion of the side surface of the upper pixel defining film UDL.

The forming of the third pixel region (S600) (see FIG. 7) may include forming a third capping pattern CP3 and a third-3 dummy pattern DM3-3 on the third upper electrode UE3 and the third-2 dummy pattern DM3-2, respectively. The forming of the third capping pattern CP3 and the third-3 dummy pattern DM3-3 may be omitted.

The dummy pattern DM3 may be defined as a portion other than the patterns formed inside the third-1 upper opening portion OPU3-1 (see FIG. 9C). For example, the third-1 to third-3 dummy patterns DM3-1. DM3-2 and DM3-3 may be defined as a third dummy pattern DM3. When the third-3 dummy pattern DM3-3 is omitted, the third-1 and third-2 dummy patterns DM3-1 and DM3-2 may be defined as the third dummy pattern DM3.

Accordingly, the second dummy pattern DM2 and the third dummy pattern DM3 may be formed on the upper pixel defining film UDL located between the second light emitting element ED2 and the third light emitting element ED3. For example, the second dummy pattern DM2 may be located at a position adjacent to the second light emitting element ED2, and the third dummy pattern DM3 may be formed at a position adjacent to the third light emitting element ED3.

The forming of the third pixel region (S600) (see FIG. 7) may include forming the first inorganic encapsulation film IEN1 so as to cover the third upper electrode UE3, the third dummy pattern DM3, and the upper pixel defining film UDL.

The forming of the third pixel region (S600) (see FIG. 7) may include forming the transparent conductive oxide films TCO1 and TCO2 on the first inorganic encapsulation film IEN1.

Referring to FIG. 13B, the forming of third pixel region (S600) (see FIG. 7) may include forming the third mask pattern MP3 on a third region BB3. The third region BB3 may mean a region overlapping the third light emitting pattern EP3 and a portion of the upper pixel defining film UDL, which surrounds the third light emitting pattern EP3, in a plan view.

Referring to FIG. 13C, the forming of the second pixel region (S500) (see FIG. 7) may include third removing the second transparent conductive oxide film TCO2, the first inorganic encapsulation film IEN1, and the third dummy pattern DM3 of a third removal region CC3. The third removal region CC3 may mean a region other than the third region BB3.

Accordingly, at least portions of the second dummy pattern DM2 and the third dummy pattern DM3 may be formed to be spaced apart from each other on the upper pixel defining film UDL located between the second light emitting element ED2 and the third light emitting pattern EP3. An opening portion formed by spacing the portions apart from each other may be defined as a dummy opening portion OPD.

In the third removal region CC3, a portion of the third dummy pattern DM3, which is located between the second mask pattern MP2 and the third mask pattern MP3, may not be removed when viewed in a plan view. For example, as illustrated in FIG. 13C, the third-1 dummy pattern DM3-1 and the third-2 dummy pattern DM3-2 of the third dummy pattern DM3 may be remained without being removed.

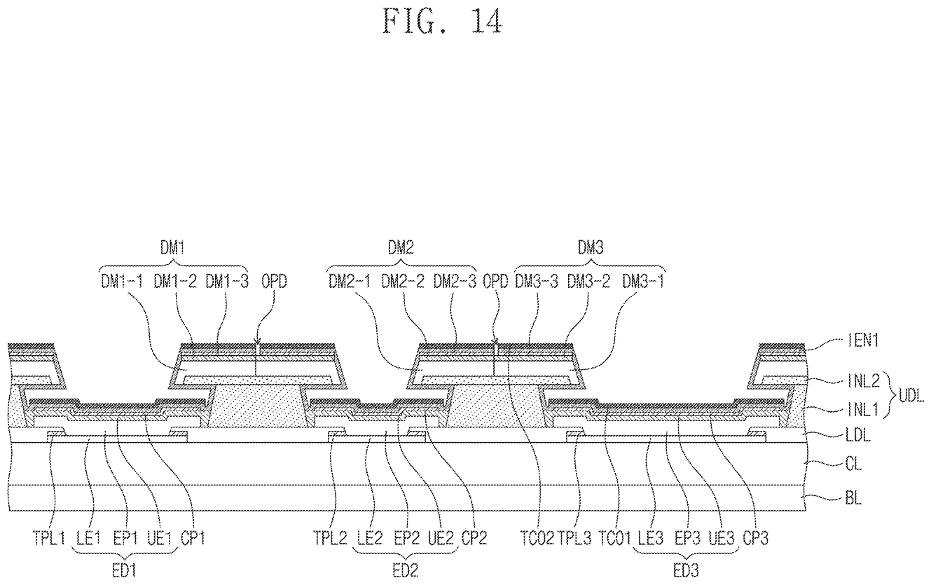

FIG. 14 is a cross-sectional view illustrating some operations of the method for manufacturing the display panel DP (see FIG. 6A) according to some embodiments of the present disclosure. FIG. 14 is a cross-sectional view illustrating an example of the removing of the first to third mask patterns MP1, MP2 and MP3 (see FIG. 13C) (S700) (see FIG. 7).

For example, the first to third mask patterns MP1, MP2 and MP3 (see FIG. 13C) may be removed by stripping. As the transparent conductive oxide films TCO1 and TCO2 are located below the first to third mask patterns MP1, MP2 and MP3 (see FIG. 13C), the first to third mask patterns MP1, MP2 and MP3 (see FIG. 13C) may be easily removed.

In the removing of the first to third mask patterns MP1, MP2 and MP3 (see FIG. 13C), the first-1 dummy pattern DM1-1, the second-1 dummy pattern DM2-1, and the third-1 dummy pattern DM3-1 may be removed together by stripping. For example, when the second-2 dummy pattern DM2-2 located between the first mask pattern MP1 and the second mask pattern MP2 is removed in the second removing described above in a plan view, and when the third-2 dummy pattern DM3-2 located between the second mask pattern MP2 and the third mask pattern MP3 is removed in the third removing described above in a plan view, the first-1 dummy pattern DM1-1, the second-1 dummy pattern DM2-1, and the third-1 dummy pattern DM3-1 may be removed together by stripping. Even when the first-1 dummy pattern DM1-1, the second-1 dummy pattern DM2-1, and the third-1 dummy pattern DM3-1 are removed together, the structure described with reference to FIG. 6C may be achieved.

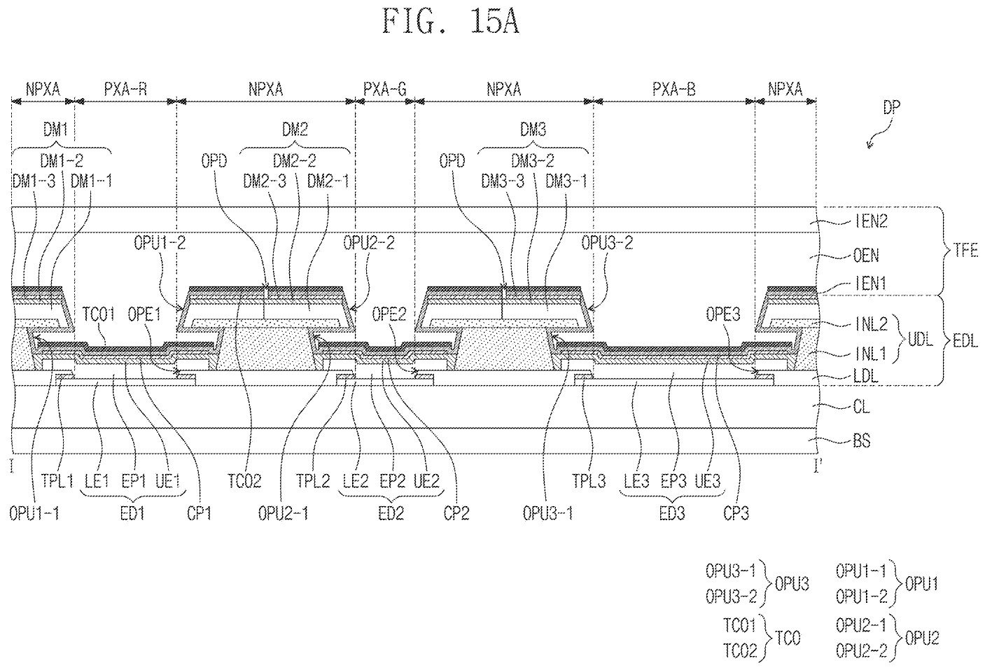

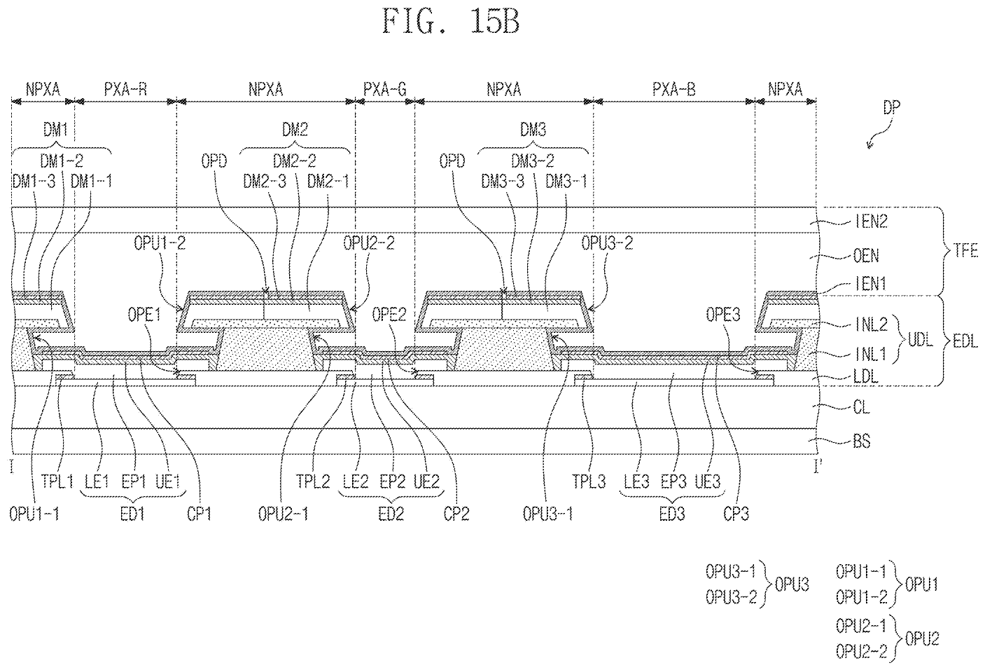

FIGS. 15A and 15B are cross-sectional views illustrating some operations of the method for manufacturing the display panel DP (see FIG. 6A) according to some embodiments of the present disclosure. FIGS. 15A and 15B are cross-sectional views illustrating an example of the forming of an organic encapsulation film OEN and a second inorganic encapsulation film IEN2 on a light emitting element layer EDL.

For example, the organic encapsulation film OEN may be formed to be relatively thicker so as to planarize a stepped portion of the light emitting element layer EDL. The organic encapsulation film OEN may be formed to fill the dummy opening portions OPD defined by the dummy patterns DM1, DM2 and DM3.

When the first-1 dummy pattern DM1-1, the second-1 dummy pattern DM2-1, and the third-1 dummy pattern DM3-1 are removed together by stripping in the removing of the first to third mask patterns MP1, MP2 and MP3 (see FIG. 13C) (S700) (see FIG. 7) described above, the organic encapsulation film OEN may be formed to fill the empty spaces resulting from the removal as illustrated in FIG. 6C.

The second inorganic encapsulation film IEN2 may be formed on the organic encapsulation film OEN to protect the light emitting element layer EDL from moisture and oxygen.

The organic encapsulation film OEN and the second inorganic encapsulation film IEN2 may be formed in a state in which the transparent conductive oxide film TCO is maintained, or may be also formed in a state in which the transparent conductive oxide film TCO is removed.

For example, as illustrated in FIG. 15A, the organic encapsulation film OEN and the second inorganic encapsulation film IEN2 may be formed in the state in which the transparent conductive oxide film TCO is maintained. Alternatively, as illustrated in FIG. 15B, the organic encapsulation film OEN and the second inorganic encapsulation film IEN2 may be formed in the state in which the transparent conductive oxide film TCO is removed. The transparent conductive oxide film TCO may be removed by wet etching.

As described above, a relatively high resolution display panel may be achieved and the display panel with the improved reliability may be provided.

The display panel manufacturing method according to some embodiments of the present disclosure may achieve the micro patterning through the exposure process. Moreover, as the light emitting patterns do not need to be exposed to the lift-off solution or covered by the resin for patterning during the process, the damage of the light emitting patterns may be prevented.

Although the embodiments of the present invention have been described, it is understood that the present invention should not be limited to these embodiments but various changes and modifications can be made by one ordinary skilled in the art within the spirit and scope of the present invention as hereinafter claimed.

Therefore, the technical scope of embodiments according to the present disclosure is not limited to the contents described in the detailed description of the specification, but should be determined by the following claims, and their equivalents.

What is claimed is:

1. A display panel comprising:
a base layer;
a circuit layer on the base layer;
a light emitting element layer on the circuit layer; and
an encapsulation layer on the light emitting element layer;
wherein the light emitting element layer comprises:
a lower electrode on the circuit layer,
a lower pixel defining film on the circuit layer and covering a portion of the lower electrode and defining a light emitting opening portion,
a light emitting pattern inside the light emitting opening portion and on the lower electrode,
an upper electrode on the light emitting pattern, and
an upper pixel defining film on the lower pixel defining film and defining an upper opening portion,
wherein the encapsulation layer comprises:
a first inorganic encapsulation film on the upper electrode and the upper pixel defining film, and
a transparent conductive oxide film on the first inorganic encapsulation film.

2. The display panel of claim 1, wherein the transparent conductive oxide film has a thickness in a range of 500 Å to 2000 Å.

3. The display panel of claim 1, wherein the transparent conductive oxide film comprises:
a first transparent conductive oxide film inside the upper opening portion; and
a second transparent conductive oxide film on the upper pixel defining film.

4. The display panel of claim 3, wherein a thickness of the first transparent conductive oxide film is equal to a thickness of the second transparent conductive oxide film.

5. The display panel of claim 3, further comprising a transparent conductive oxide film opening portion defined by the second transparent conductive oxide film on the upper pixel defining film.

6. The display panel of claim 1, wherein the light emitting element layer further comprises a protective pattern on the lower electrode and covered by the lower pixel defining film.

7. The display panel of claim 1, wherein the upper pixel defining film comprises:
a first inorganic film on the lower pixel defining film; and
a second inorganic film on the first inorganic film.

8. The display panel of claim 7, wherein the second inorganic film has a side surface that protrudes toward a center of the lower electrode more than a side surface of the first inorganic film in a plan view.

9. The display panel of claim 7, wherein each of the first inorganic film and the second inorganic film comprise an inorganic insulation film or a conductive metal.

10. The display panel of claim 7, wherein:
the upper pixel defining film further comprises a third inorganic film above the lower pixel defining film and below the first inorganic film, and
the third inorganic film has a side surface that protrudes toward a center of the upper opening portion more than a side surface of the first inorganic film in a plan view.

11. The display panel of claim 1, wherein:
the light emitting element layer further comprises a capping pattern on the upper electrode, and
the encapsulation layer further comprises:
an organic encapsulation film on the first inorganic encapsulation film and the transparent conductive oxide film, and
a second inorganic encapsulation film on the organic encapsulation film.

12. A display panel comprising:
a base layer;
a circuit layer on the base layer; and
a light emitting element layer on the circuit layer,
wherein the light emitting element layer comprises:
a lower electrode on the circuit layer,
a lower pixel defining film on the circuit layer and covering a portion of the lower electrode and defining a light emitting opening portion,
a first light emitting pattern inside the light emitting opening portion and on the lower electrode,
an upper electrode on the first light emitting pattern,
an upper pixel defining film on the lower pixel defining film, and
a dummy pattern on the upper pixel defining film,
wherein the dummy pattern comprises a first dummy pattern and a second dummy pattern that are on a same layer.

13. The display panel of claim 12, wherein
the light emitting element layer further comprises a second light emitting pattern configured to emit light of a color different from that of the first light emitting pattern,
the first dummy pattern includes a light emitting material the same as a light emitting material included in the first light emitting pattern, and
the second dummy pattern includes a light emitting material the same as a light emitting material included in the second light emitting pattern.

14. The display panel of claim 12, further comprising an encapsulation layer on the light emitting element layer,
wherein the encapsulation layer comprises:
a first inorganic encapsulation film on the upper electrode and the upper pixel defining film, and
a transparent conductive oxide film on the first inorganic encapsulation film.

15. The display panel of claim 12, wherein the light emitting element layer further comprises a protective pattern on the lower electrode and covered by the lower pixel defining film.

16. A method of manufacturing a display panel, the method comprising:
preparing a preliminary display panel that includes a base layer, a circuit layer on the base layer, first to third lower electrodes on the circuit layer and spaced apart from each other, a preliminary lower pixel defining film on the circuit layer and covering the first to third lower electrodes, and a preliminary upper pixel defining film on the preliminary lower pixel defining film;
forming an upper pixel defining film configured to define each of first to third upper opening portions by removing regions of the preliminary upper pixel defining film, each of which has at least a portion overlapping each of the first to third lower electrodes in a plan view;
forming a lower pixel defining film configured to define first to third light emitting opening portions by removing portions of the preliminary lower pixel defining film, which are exposed by the first to third upper opening portions;
forming a first light emitting pattern and a first-1 dummy pattern by depositing a first light emitting material on the first to third lower electrodes and the upper pixel defining film;
forming a first upper electrode and a first-2 dummy pattern on the first light emitting pattern and the first-1 dummy pattern, respectively, so as to be in contact with at least a portion of a side surface of the upper pixel defining film on the first light emitting pattern;
forming a first inorganic encapsulation film so as to cover the first upper electrode, the first-1 dummy pattern, the first-2 dummy pattern, and the upper pixel defining film;
forming a transparent conductive oxide film on the first inorganic encapsulation film; and
first removing the transparent conductive oxide film, the first inorganic encapsulation film, the first-1 dummy pattern, and the first-2 dummy pattern of a first removal region other than a first region that overlaps the first light emitting pattern and a portion of the upper pixel defining film surrounding the first light emitting pattern in a plan view.

17. The method of claim 16, wherein the first removing comprises:
forming a first mask pattern on the first region;
removing the transparent conductive oxide film of the first removal region by wet etching; and
removing the first inorganic encapsulation film, the first-1 dummy pattern, and the first-2 dummy pattern of the first removal region by dry etching.

18. The method of claim 17, further comprising:
forming a second light emitting pattern and a second-1 dummy pattern by depositing a second light emitting material on the first region and the first removal region;
forming a second upper electrode and a second-2 dummy pattern on the second light emitting pattern and the second-1 dummy pattern, respectively, so as to be in contact with at least a portion of the side surface of the upper pixel defining film;
forming the first inorganic encapsulation film so as to cover the second upper electrode, the second-1 dummy pattern, the second-2 dummy pattern, and the upper pixel defining film;
forming the transparent conductive oxide film on the first inorganic encapsulation film; and
second removing the transparent conductive oxide film, the first inorganic encapsulation film, the second-1 dummy pattern, and the second-2 dummy pattern of a second removal region other than a second region that overlaps the second light emitting pattern and a portion of the upper pixel defining film surrounding the second light emitting pattern in a plan view,
wherein the second removing comprises forming a second mask pattern on the second region.

19. The method of claim 18, further comprising:
forming a third light emitting pattern and a third-1 dummy pattern by depositing a third light emitting material on the second region and the second removal region;
forming a third upper electrode and a third-2 dummy pattern on the third light emitting pattern and the third-1 dummy pattern, respectively, so as to be in contact with at least a portion of the side surface of the upper pixel defining film;
forming the first inorganic encapsulation film so as to cover the third upper electrode, the third-1 dummy pattern, the third-2 dummy pattern, and the upper pixel defining film;
forming the transparent conductive oxide film on the first inorganic encapsulation film; and
third removing the transparent conductive oxide film, the first inorganic encapsulation film, the third-1 dummy pattern, and the third-2 dummy pattern of a third removal region other than a third region that overlaps the third light emitting pattern and a portion of the upper pixel defining film surrounding the third light emitting pattern in a plan view,
wherein the third removing comprises forming a third mask pattern on the third region.

20. The method of claim 19, further comprising removing the first to third mask patterns by stripping.
